(19) United States
(12) Patent Application Publication
(10) Pub. No.: US 2013/0134608 A1
(43) Pub. Date: May 30, 2013

(54) FUNCTIONAL PARTICLE, FUNCTIONAL PARTICLE GROUP, FILLER, RESIN COMPOSITION FOR ELECTRONIC COMPONENT, ELECTRONIC COMPONENT AND SEMICONDUCTOR DEVICE

(71) Applicants: Tadayoshi Ozasa, Tokyo (JP); Tatsumi Kawaguchi, Tokyo (JP); Shogo Nakano, Tokyo (JP)

(72) Inventors: Tadayoshi Ozasa, Tokyo (JP); Tatsumi Kawaguchi, Tokyo (JP); Shogo Nakano, Tokyo (JP)

(73) Assignee: SUMITOMO BAKELITE CO., LTD., Tokyo (JP)

(21) Appl. No.: 13/814,163

(22) PCT Filed: Mar. 2, 2011
(86) PCT No.: PCT/JP2011/001215

§ 371 Date: Feb. 4, 2013

(30) Foreign Application Priority Data
Aug. 5, 2010 (JP) 2010-176054

(51) Int. Cl. H01L 23/29

(52) U.S. Cl. CPC H01L 23/295
USPC 257/789; 523/466

(57) ABSTRACT

A functional particle (100) contains an inorganic particle (101), a first layer (103) coating the inorganic particle (101), and a second layer (105) coating the first layer (103). Any one or two component(s) of a resin, a curing agent and a curing accelerator is (are) contained in the first layer (103), and the others are (is) contained in the second layer (105).

### TECHNICAL FIELD

The present invention relates to a functional particle, a functional particle group, a filler, a resin composition for electronic component, an electronic component and a semiconductor device.

### BACKGROUND ART

In compositions containing inorganic particles, resins and curing agents thereof, it is critical to uniformly formulate the respective components in the compositions at predetermined proportions. Patent Document 1 discloses a technology related to such composition. Patent Document 1 describes a method for producing an epoxy resin composition comprising an epoxy resin, a curing agent, an inorganic filler and a curing catalyst as essential constituents. More specifically, it is described that a surface treatment is conducted for spherical silica with an epoxy resin and/or a curing agent in advance, and then the obtained treated silica is mixed with a curing catalyst or the like and the mixture is kneaded to obtain an epoxy resin composition. It is also described that the surfaces of the inorganic filler are uniformly coated with the resin by previously conducting the surface treatment to provide significantly reduced generation of voids during the process for encapsulating the semiconductor device, thereby achieving enhanced moldability.

### RELATED DOCUMENTS

### Patent Documents

### [Patent Document 1]

Japanese Laid-Open Patent Publication No. H08-27,361 (1996)

### DISCLOSURE OF THE INVENTION

However, the present inventors investigated the technology descried in the above-described Patent Document, and found that the following aspects are needed to be improved. That is to say that Patent Document 1 involves mixing the obtained treated silica with the curing catalyst and then the mixture is kneaded, which may cause a separation of the treated silica from the curing catalyst component in the compositions or cause a compositional irregularity. In addition, the mixing and the kneading may cause a reaction among the resin, the curing agent, and the curing catalyst during storage, so that a cure may possibly be progressed, and therefore the feature of the storage stability is needed to be improved.

According to one aspect of the present invention, there is provided functional particle, comprising: a base particle composed of an inorganic material; a first layer coating the base particle; and a second layer coating the first layer, wherein the first layer comprises any one or two component selected from an epoxy resin, a curing agent for said epoxy resin and a curing accelerator for said epoxy resin, and the second layer comprises the other components.

According to another aspect of the present invention, there is provided a filler composed of the functional particle according to the present invention.

In the above-described aspect of the present invention, the first and the second layers are provided on the base particle, and the epoxy resin, its curing agent and its curing accelerator are contained in any one of the first layer and the second layer, respectively. The epoxy resin, the curing agent and the curing accelerator are contained a layer disposed over the base particle and at least one among the above-described three components is provided in another separate layer, so that the respective components are stably sustained at a predetermined formulation on the particle. This effectively inhibits the deviation and the fluctuation of the components and the deterioration of the storage stability due to the reaction among the respective components in the filler containing the functional particle according to the present invention. Further, this can be preferably employed as, for example, a resin composition for electronic component that provides an encapsulation of a semiconductor element, which can provide improved production stability for the semiconductor element. Further, it is configured that the base particle surface is coated with the resin, the curing agent and the curing accelerator, so that, even if the filler containing the functional particle according to the present invention is a tablet shaped filler, the composition exhibiting improved tablet formability can be obtained.

Here, “the first and the second layers cover the base particle and the first layer, respectively,” in the present specification, means that at least a part of the surface of the base particle and the first layer is coated. Thus, this is not limited to the mode of covering the entire surface, and also includes, for example, a mode of covering the entire surface viewed from a specific cross section, and a mode of covering a specific part of the surface. In view of further effectively inhibiting the variation of the composition by respective particles, it is preferable to coat the entire surface at least when it is viewed from a specific cross section, and it is further preferable to coat the entire surface.

Further, the first layer may be directly contacted with the base particle, or an interposing layer may be provided therebetween. This is similar to the relation of the second layer and the first layer, in which these may create direct contact or an interposing layer may be provided therebetween.

According to further aspect of the present invention, there is provided a functional particle group containing a first coated particle including a base particle composed of an inorganic material coated with a resin; and a second coated particle coated with a curing agent for said resin, said first and second coated particles are mixed according to a prescription. More specifically, according to the above-described aspect of the present invention, there is provided a functional particle group containing a first coated particle configured of a base particle composed of an inorganic material coated with a resin, and a second coated particle configured of said base particle coated with a curing agent for said resin.

According to the further aspect of the present invention, there is provided a filler composed of said functional particle group according to the present invention.

In the present invention, the functional particle group is configured to consist of the first coated particle, in which the material for coating the base particle is the resin, and the second coated particle, in which the material for coating the base particle is the curing agent for the resin. The resin and the curing agent are provided over the different base particles to configure the base particles having different homogeneous coatings of the resin and the curing agent, respectively. Further, this can inhibit the fluctuation of the formulation due to the unwanted reaction of the resin and the curing agent during storage, so that, when the resin and the curing agent coexist in the functional particle group, the respective components are stably sustained on the particle at a predetermined formulation. Further, the surface of the base particle is coated to allow obtaining a composition exhibiting improved tablet formability.

Here, the materials for coating the base particle such as the resin, the curing agent and the like may be provided over the base particle in the form of a layer. This can provide further improved homogeneity of the coating provided over the particle. Further, in the first and the second coated particles, the base particle may be in direct contact with the resin or the curing agent, or the interposing layer may be provided therewith.

Further, in the present specification, “the base particle is coated with a material such as the resin, the curing agent of the resin, and other component and the like” indicates coating at least a part of the surface of the base particle layer. Thus, it is not limited to the mode of coating the entire surface, but also includes, for example, the mode of coating the entire surface viewed from the specific cross section and the mode of coating the specific part of the surface. In view of further effectively inhibiting the variation of the composition by respective particles, it is preferable to coat the entire surface at least when it is viewed from a specific cross section, and it is further preferable to coat the entire surface.

According to yet other aspect of the present invention, there is provided a resin composition for an electronic component containing said filler according to the present invention. Further, according to yet other aspect of the present invention, there is provided an electronic component obtained by molding said resin composition for the electronic component according to the present invention. Further, according to yet other aspect of the present invention, there is provided a semiconductor device obtained by encapsulating a semiconductor element with said resin composition for the electronic component according to the present invention.

According to the present invention, the resin and the curing agent can be stably sustained over the base particle at the predetermined formulation.

### BRIEF DESCRIPTION OF THE DRAWINGS

FIG. 1 is a cross-sectional view, illustrating a configuration of a functional particle in an embodiment.

FIG. 2 is a cross-sectional view, illustrating a configuration of a functional particle in an embodiment.

FIG. 3 is a cross-sectional view, illustrating a configuration of a semiconductor device in an embodiment.

FIG. 4 is a cross-sectional view, illustrating a configuration of a coated particle in an embodiment.

FIG. 5 is a cross-sectional view, illustrating a configuration of a functional particle group in an embodiment.

### DESCRIPTION OF EMBODIMENTS

Preferable embodiments of the present invention will be described in detail below, in reference to the annexed figures. In the following descriptions concerning the figures, the same numeral is assigned to the same element, and the described thereof is not presented.

### First Embodiment

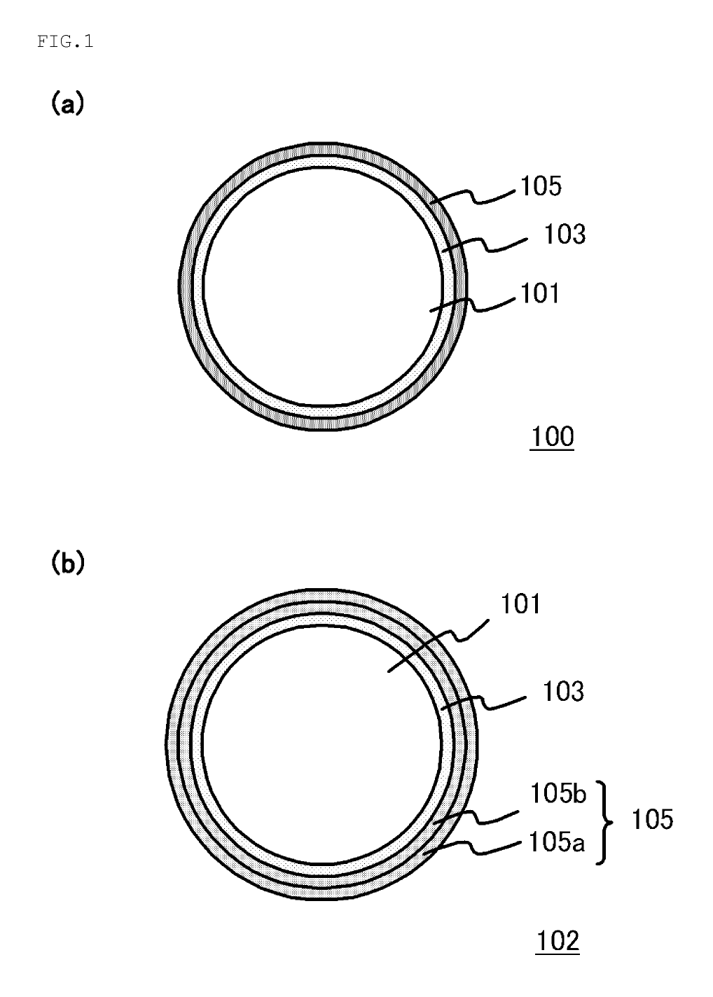

FIG. 1(a) is a cross-sectional view, illustrating a configuration of a functional particle in the present embodiment. A functional particle 100 shown in FIG. 1(a) includes a base particle composed of an inorganic material (inorganic particle 101), a first layer 103 that coats the inorganic particle 101, and a second layer 105 that coats the first layer 103.

In the exemplary implementation of FIG. 1(a), the first layer 103 is in contact with the surface of the inorganic particle 101, and covers the entire surface of the inorganic particle 101. Further, the second layer 105 is in contact with the first layer 103, and covers the entire surface of the first layer 103. In addition, the first layer 103 and the second layer 105 are provided to have uniform thicknesses in a cross-sectional view as a preferable aspect.

While FIG. 1(a) shows the exemplary implementation having smooth interface between the inorganic particle 101 and the first layer 103 and smooth interface between the first layer 103 and the second layer 105, these interfaces may alternatively have irregularity.

Further, any one or two of the epoxy resin, the curing agent and the curing accelerator is (are) contained in the first layer 103, and the other of these are (is) contained in the second layer 105. Here, the first layer 103 and the second layer 105, respectively, may contain the component other than the resin, the curing agent and the curing accelerator.

Typically, any one of the epoxy resin, the curing agent and the curing accelerator is contained in the first layer 103, and the other two thereof are contained in the second layer 105. Alternatively, any two of the epoxy resin, the curing agent and the curing accelerator are contained in the first layer 103, and the other one is contained in the second layer 105.

More specifically, it may be configured that, among the epoxy resin, the curing agent and the curing accelerator, the curing agent and the curing accelerator are contained in an identical layer, and the epoxy resin is contained in another layer. It is configured that one of the first layer 103 and the second layer 105 contains the curing agent and the curing accelerator and the other contains the epoxy resin to provide further improved storage stability of the filler composed of the functional particle 100. For example, the time degradation stored at 40 degrees C. can be effectively inhibited.

Alternatively, other specific aspect may be configured that the resin and the curing agent are contained in the identical layer and the curing accelerator is contained in another layer. It may be configured that one of the first layer 103 and the second layer 105 contains the resin and the curing agent, and the other contains the curing accelerator, such that the storage stability of the filler composed of the functional particle 100 can be further improved. For example, the time degradation stored at 40 degrees C. can be effectively inhibited.

The thickness of the layer containing the epoxy resin, which is one of the first layer 103 and the second layer 105, is not particularly limited, as long as the thickness satisfies the required blending amount for inducing the cure reaction, and for example, may be equal to or larger than 5 nm, and preferably equal to or larger than 50 nm, and on the other hand, in view of providing further improved productivity, for example, may be equal to or smaller than 50 μm, and preferably equal to or smaller than 5 μm.

Also, the thickness of the layer containing the curing agent, which is one of the first layer 103 and the second layer 105, is not particularly limited, as long as the thickness satisfies the required blending amount for inducing the cure reaction, and for example, may be equal to or larger than 5 nm, and preferably equal to or larger than 50 nm, and on the other hand, in view of providing further improved productivity, for example, may be equal to or smaller than 50 μm, and preferably equal to or smaller than 5 μm.

Also, the thickness of the layer containing the curing accelerator, which is one of the first layer 103 and the second layer 105, is not particularly limited, as long as the thickness satisfies the required blending amount for inducing the cure reaction, and for example, may be equal to or larger than 1 nm, and preferably equal to or larger than 5 nm, and it is not necessary to form a uniform layer, but on the other hand, in view of providing further improved productivity, for example, may be equal to or smaller than 50 μm, and preferably equal to or smaller than 5 μm.

A specific example of constituents of the functional particle 100 will be described below. One component may be employed for a single constituent, or a combination of a plurality of components may be alternatively employed.

Typical material for the inorganic particle 101 includes, for example: silica powders such as fused crushed silica powder, fused spherical silica powder, crystal silica powder, secondary agglomerated silica powder and the like; alumina; titanium white; aluminum hydroxide; talc; clay; mica; and glass fiber.

Among these, in view of the installation reliability in the use for an electronic component and a sealant of a semiconductor device, it is preferable to employ a spherical particle composed of an inorganic material of one, two or more materials(s) selected from the group consisting of silica, alumina and silicon nitride for the inorganic particle 101. In these inorganic materials, silica is particularly preferable. Alternatively, in view of the mechanical strength, it is preferable to employ a fibrous particle composed of a fiber material such as a glass fiber and the like for the inorganic particle 101. Alternatively, the inorganic particle 101 may be a particle obtained by processing a nonwoven fabric such as a glass nonwoven fabric and the like into particle-shape.

In addition, the particle shape of the inorganic particle 101 is not particularly limited, and for example: crushed shape; spherical shape such as substantially spherical, spherical and the like; fibrous shape; probe shape and the like. Mean particle diameter in the case that the inorganic particle 101 is a spherical particle may be, in view of inhibiting the agglomeration of particles, for example equal to or larger than 1 μm, and preferably equal to or larger than 10 μm. In addition, from the viewpoint of the smoothness, the particle size of the inorganic particle 101 may be for example, equal to or smaller than 100 μm, and preferably equal to or smaller than 50 μm.

In addition to above, a combination of particles having different sizes may be employed for the inorganic particle 101. For example, when the inorganic particle 101 is employed for a filler employed in a sealant of an electronic component, the use of the combination of the particles having different sizes provides enhanced flowability, such that higher filler loading can be achieved to provide further improved package reliability such as solder thermal resistance and the like. In this case, the inorganic particle for the use in combination with the inorganic particle having the above-mentioned mean particle diameter may have the mean particle diameter of, for example, equal to or larger than 50 nm and preferably equal to or larger than 200 nm, in view of inhibiting the agglomeration of the particles. In view of enhancing the flowability, it may be, for example, equal to or smaller than 2.5 μm, and preferably equal to or smaller than 1 μm.

Next, the epoxy resin, the resin curing agent of the resin and the curing accelerator (curing catalyst) of the resin will be described.

The epoxy resin generally includes whole of monomer, oligomer, and polymer, having two or more epoxy groups in a single molecule, and the molecular weight and the molecular structure thereof are not particularly limited. The epoxy resin typically includes, for example: difunctionalized or crystalline epoxy resins such as biphenyl type epoxy resin, bisphenol A based epoxy resin, bisphenol F type epoxy resin, stilbene type epoxy resin, hydroquinone type epoxy resin and the like; novolac type epoxy resins such as cresol novolac type epoxy resin, phenol novolac type epoxy resin, naphthol novolac type epoxy resin and the like; phenol aralkyl type epoxy resins such as phenylene skeleton-containing phenol aralkyl type epoxy resin, biphenylene skeleton-containing phenol aralkyl type epoxy resin, phenylene skeleton-containing naphthol aralkyl type epoxy resin and the like; trifunctional type epoxy resins such as triphenolmethane type epoxy resin and alkyl-modified triphenolmethane type epoxy resin and the like; modified phenol-type epoxy resins such as dicyclopenta diene-modified phenol type epoxy resin, terpene-modified phenol type epoxy resin and the like; and heteroring-containing epoxy resins such as triazine nucleus-containing epoxy resin and the like. One of these may be employed alone, or a combination of two or more of these may also be employed.

When the functional particle 100 is employed for the filler employed in the sealant of the electronic component, it is preferable in view of providing improved package reliability to employ, for example: phenol novolac type epoxy resin, cresol novolac type epoxy resin and the like; biphenyl type epoxy resins; phenol aralkyl type epoxy resins such as phenylene skeleton-containing phenol aralkyl type epoxy resin, biphenylene skeleton-containing phenol aralkyl type (or biphenyl aralkyl type) epoxy resin, phenylene skeleton-containing naphthol aralkyl type epoxy resin and the like; trifunctional type epoxy resins such as triphenol methane type epoxy resin and alkyl-modified triphenolmethane type epoxy resin and the like; modified phenol type epoxy resins such as dicyclopenta diene-modified phenol type epoxy resin, terpene-modified phenol type epoxy resin and the like; heteroring-containing epoxy resins such as triazine nucleus-containing epoxy resin and the like; and arylalkylene type epoxy resin.

The available curing agent is not particularly limited as long as it is capable of reacting with the epoxy resin to cause a cure, and specific examples of those includes: aliphatic polyamines such as diethylenetriamine (DETA), triethylenetetramine (TETA), metaxylene diamine (MXDA) and the like; aromatic polyamines such as diaminodiphenyl methane (DDM), m-phenylenediamine (MPDA), diaminodiphenylsulphone (DDS) and the like, and additionally polyamine compounds containing dicyandiamide (DICY), organic acid dihydrazide and the like; alicyclic acid anhydride such as hexahydrophthalic anhydride (HHPA), methyltetrahydrophthalic anhydride (MTHPA) and the like; acid anhydrides containing aromatic acid anhydride such as trimellitic anhydride (TMA), pyromellitic dianhydride (PMDA), benzophenone tetracarboxylic acid (BTDA) and the like; polyphenol compound such as novolac type phenolic resin, and phenol aralkyl type epoxy resins such as phenylene skeleton-containing phenol aralkyl resin, biphenylene skeleton-containing phenol aralkyl (or biphenyl aralkyl) resin, phenylene skeleton-containing naphthol aralkyl resin and the like, and bisphenol compounds such as bisphenol A and the like; poly mercaptan compounds such as polysulphide, thioester, thioether and the like; isocyanate compounds such as isocyanate prepolymer, blocked isocyanate and the like; organic acids such as carboxylic acid-containing polyester resin and the like; tertiaryamine compounds such as benzil dimethylamine (BDMA), 2,4,6-tridimethylaminomethyl phenol (DMP-30) and the like; imidazole compounds such as 2-methyl imidazole, 2-ethyl-4-methyl imidazole (EMI24) and the like; Lewis acids such as boron trifluoride (BF₃) complex and the like; phenolic resins such as novolac type phenolic resin, resol type phenolic resin and the like; urea resins such as methylol group-containing urea resin; and melamine resins such as methylol group-containing melamine resin and the like.

Among these curing agents, it is particularly preferable to employ a phenolic resin. The phenolic resin employed in the present embodiment generally includes whole of monomer, oligomer, and polymer, having two or more phenolic hydroxyl groups in a single molecule, and the molecular weight and the molecular structure thereof are not particularly limited, and typically includes for example, phenol novolac resin, cresol novolac resin, dicyclopenta diene-modified phenolic resin, terpene-modified phenolic resin, triphenolmethane type resin phenolaralkyl resin (having phenylene skeleton, biphenylene skeleton and the like) and the like, and one of these may be employed alone, or a combination of two or more of these may also be employed.

In addition, the curing accelerator may be employed in the present invention as long as this accelerates the reaction of the epoxy resin with the curing agent, and typically an accelerator employed for the general epoxy resin composition for encapsulating the semiconductor chip can be utilized. Specific examples thereof may include: phosphorus atom-containing compounds such as organic phosphines, tetra substituted phosphonium compounds, phospho betaine compounds, tertiary phosphine exemplified by adduct of phosphine compound with quinone compound, adduct of phosphonium compound with a silane compound and the like, quaternary phosphonium, adduct of tertiary phosphine with electron-deficient compound and the like; tertiary amine compounds exemplified by 1,8-diazabicyclo(5,4,0)undecene-7, benzil dimethylamine, 2-methyl imidazole and the like; and nitrogen atom-containing compounds such as annular or non-cyclic amidine compounds and the like. One of these curing accelerators may be employed alone, or a combination of two or more of these may also be employed. Among these: phosphorus atom-containing compound is preferable; and in particular, tetra substituted phosphonium compound is preferable, taking the fact that improved flowability can be achieved by providing reduced viscosity of the semiconductor encapsulating resin composition and the fact that rate for initial cure reaction can be enhanced, into consideration; and in addition, in consideration of lower elastic modulus at higher temperature of the cured product of the semiconductor encapsulating resin composition, phospho betaine compounds and adduct of phosphine compound with quinone compound are preferable, and further, in consideration of the hidden curability, adduct of phosphonium compound with silane compound is preferable.

Typical organic phosphines include, for example: primary phosphines such as ethylphosphine, phenylphosphine and the like; secondary phosphines such as dimethylphosphine, diphenylphosphine and the like; tertiary phosphines such as trimethylphosphine, triethylphosphine, tributylphosphine, triphenylphosphine and the like.

Typical tetra substituted phosphonium compound may be compounds represented by the following general formula (4);

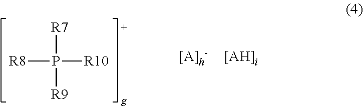

wherein in the general formula (4),
P is phosphorus atom,
R7, R8, R9 and R10 are aromatic group, or alkyl group, and they may be the same or different,
A is anion of aromatic organic acid having at least one functional group selected from hydroxyl group, carboxylic group and thiol group in its aromatic ring,
AH is an aromatic organic acid having at least one functional group selected from hydroxyl group, carboxylic group and thiol group in its aromatic ring, and
g, h are integers of 1 to 3, i is an integer of 0 to 3, and g=h.

The compounds represented by the above-described general formula (4) may be obtained by, for example, the following manner, though the configuration thereof is not limited thereto. First of all, tetra substituted phosphonium halide, an aromatic organic acid and a base are added in an organic solvent, and are uniformly mixed to generate aromatic organic acid anion in the solution system. Subsequently, water is added to allow causing a precipitation of the compounds represented by the above-described general formula (4). It is preferable in the compound represented by the above-described general formula (4) that R7, R8, R9 and R10, which are bound to phosphorus atom, is phenyl group, and AH is a compound having hydroxyl group in aromatic ring, or in other words, phenols, and A is anion of phenols.

Typical phospho betaine compound may be compounds represented by the following general formula (5);

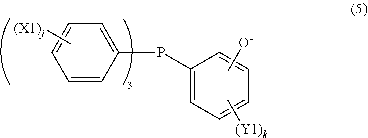

wherein in the general formula (5),
P is phosphorus atom,
X1 is alkyl group of C1 to C3,
Y1 is hydroxyl group, and
j, k are integers of 0 to 3.

The compounds represented by the above-described general formula (5) may be obtained by, for example, the following manner. It is obtained through a process for causing a substitution of tri aromatic substituted phosphine with diazonium group contained in diazonium salt, by bringing tri aromatic substituted phosphine, which is a tertiary phosphine, into contact with diazonium salt. However, it is not intended to limit thereto.

Typical adduct of a phosphine compound with a quinone compound may be compounds represented by the following general formula (6);

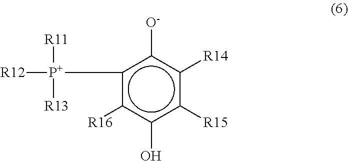

wherein in the general formula (6),
P is phosphorus atom,
R11, R12 and R13 are alkyl group of C1 to C12 or aryl group of C6 to C12, and they may be the same or different,
R14, R15, and R16 are hydrogen atom or hydrocarbon group of C1 to C12, and they may be the same or different, and R14 and R15 may be bound to create cyclic structure.

Typical phosphine compound employed for the adduct of a phosphine compound with a quinone compound preferably includes: compounds having no substituted group to aromatic ring such as triphenylphosphine, tris(alkylphenyl)phosphine, tris(alkyloxyphenyl)phosphine, trinaphthyl phosphine, tris(benzil)phosphine and the like; or compounds having substituted group, which is typically alkyl group, alkoxyl group and the like; and typical alkyl group and alkoxyl group are groups of C1 to C6. In view of the ease of access to the product, triphenylphosphine is preferable.

Typical quinone compound employed for the adduct of a phosphine compound with a quinone compound preferably includes o-benzoquinone, p-benzoquinone and anthraquinones, and among these, p-benzoquinone is preferable in view of the storage stability.

Typical process for producing the adduct of a phosphine compound with a quinone compound may include contacting and mixing of organic tertiary phosphine and benzoquinones in a solvent that can dissolve both compounds to obtain the adduct. Typical solvent includes ketones such as acetone, methyl ethyl ketone and the like, and preferably a solvent exhibiting lower solubility to the adduct. However, it is not intended to limit thereto.

It is preferable to employ a compound represented by the above-described general formula (6), in which R11, R12 and R13, which are bound to phosphorus atom, are phenyl group, and R14, R15 and R16 are atomic hydrogen, or in other words, it is preferable to employ a compound created by an addition of 1,4-benzoquinone and triphenylphosphine, in view of providing reduced elastic modulus of the cured product of the semiconductor encapsulating resin composition at high temperature.

Typical adduct of a phosphonium compound with a silane compound may be compounds represented by the following general formula (7);

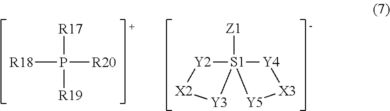

wherein in the general formula (7),
P is phosphorus atom,
Si is silicon atom,
R17, R18, R19 and R20 are organic group or fatty oil group having aromatic ring or heteroring, and they may be the same or different,
X2 is organic group bound to with group Y2 and Y3,
X3 is organic group bound to with group Y4 and Y5,
Y2 and Y3 are groups, which are formed by emitting proton from proton donating substitutional groups, and they may be the same or different, and groups Y2 and Y3 in one molecule are bound to silicon atom to form chelate structure,
Y4 and Y5 are groups, which are formed by emitting proton from proton donating substitutional groups, and groups Y4 and Y5 in one molecule are bound to silicon atom to form chelate structure,
X2 and X3 may be the same or different, and Y2, Y3, Y4 and Y5 may be the same or different, and
Z1 is organic group or fatty oil group having aromatic ring or heteroring.

In the above-described general formula (7), R17, R18, R19 and R20 may typically be, for example, phenyl group, ethylphenyl group, methoxyphenyl group, hydroxyphenyl group, naphthyl group, hydroxy naphthyl group, benzyl group, methyl group, ethyl group, n-butyl group, n-octyl group and cyclohexyl group and the like, and among these, aromatic groups having substitutional group such as phenyl group, methylphenyl group, methoxyphenyl group, hydroxyphenyl group, hydroxy naphthyl group and the like, or aromatic group having no substitution group may be more preferable.

In addition, in the above-described general formula (7), X2 is an organic group bound to Y2 and Y3. Similarly, X3 is an organic group bound to groups Y5 and Y5. Y2 and Y3 are groups created by emitting proton from proton donating substitutional group, and groups Y2 and Y3 in a single molecule binds to silicon atom to create chelate structure. Similarly, Y4 and Y5 are groups created by emitting proton from proton donating substitutional group, and groups Y4 and Y5 in a single molecule binds to silicon atom to create chelate structure. Groups X2 and X3 may be the same or different from each other, and Groups Y2, Y3, Y4 and Y5 may be the same or different from each other.

The groups represented by —Y2-X2-Y3- and —Y4-X3-Y5- in the above-described general formula (7) are configured by emitting two proton from a proton donor, and typical proton donor includes, for example, catechol, pyrogallol, 1,2-dihydroxynaphthalene, 2,3-dihydroxynaphthalene, 2,2′-biphenol, 1,1′-bi-2-naphthol, salicylic acid, 1-hydroxy-2-naphthoic acid, 3-hydroxy-2-naphthoic acid, chloranilic acid, tannic acid, 2-hydroxybenzyl alcohol, 1,2-cyclohexane diol, 1,2-propanediol and glycerol, and among these, catechol, 1,2-dihydroxynaphthalene, and 2,3-dihydroxynaphthalene may be more preferable.

In addition, Z1 in the above-described general formula (7) represents an organic group or an aliphatic group having aromatic ring or heteroring, and specific examples of these may include: aliphatic groups such as methyl group, ethyl group, propyl group, butyl group, hexyl group and octyl group and the like; aromatic groups such as phenyl group, benzyl group, naphthyl group and biphenyl group and the like; and organic groups having reactive substitutional group such as glycidyloxypropyl group, mercaptopropyl group, aminopropyl group and vinyl group and the like; and among these, methyl group, ethyl group, phenyl group, naphthyl group and biphenyl group may be more preferable, in view of enhanced thermal stability.

Typical production process for the adduct of a phosphonium compound with a silane compound may involve: a silane compound such as phenyl trimethoxysilane and the like and a proton donor such as 2,3-dihydroxynaphthalene and the like are added to a flask containing methanol; and are dissolved therein; and then sodium methoxide-methanol solution is dropped therein at a room temperature while stirring. Further, a previously prepared solution of tetra substituted phosphonium halide such as tetraphenylphosphonium bromides dissolved in methanol is dropped therein at a room temperature while stirring to create a precipitation of a crystallized product. Filtration, rinsing and vacuum drying are conducted for the precipitated crystallized product to obtain the adduct of a phosphonium compound with a silane compound. However, it is not intended to limit thereto.

More specific configuration of resins, curing agents and curing accelerators for the functional particle 100 may be, for example, the following exemplary configuration: inorganic particle 101: 87 parts by mass; the first layer 103: 6.1 parts by mass of biphenyl type epoxy resin and 4.0 parts by mass of phenol novolac resin; and the second layer 105: 0.15 parts by mass of triphenylphosphine.

In addition, the functional particle 100 may contain a resin other than the epoxy resin. For example, curable resin may be employed for such other resin. Typical curable resin may include the following thermosetting resins. For example, phenolic resins, cyanate ester resins, urea resins, melamine resins, unsaturated polyester resins, bismaleimide resins, polyurethane resins, diallyphthalate resins silicone resins, resins having benzoxazin ring and the like, may be exemplified.

Typical phenolic resin includes: novolac type phenolic resins such as phenol novolac resin, cresol novolac resin, bisphenol A based novolac resin and the like; methylol type resol resins; dimethylene ether type resol resins; and resol type phenolic resins such as oil-modified resol phenolic resins modified with tung oil, flaxseed oil, walnut oil and the like. One of these may be employed alone, or a combination of two or more of these may also be employed.

In addition, as typical cyanate ester resin, a compound obtained by a reaction of a halogen cyanide compound with a phenol, or a product obtained by a pre-polymerization thereof by heating or the like, may be employed. Specific conformation may include, for example, novolac type cyanate resins, and bisphenol type cyanate resins and the like, such as bisphenol A type cyanate resin, bisphenol E type cyanate resin, tetramethyl bisphenol F type cyanate resin and the like. One of these may be employed alone, or a combination of two or more of these may also be employed.

Next, a production process for the functional particle 100 will be described. The functional particle 100 may be obtained by consecutively conducting, for example: a step for forming the first layer 103 over a surface of the inorganic particle 101; and a step for forming the second layer 105 over a surface of the first layer 103.

More specifically, the inorganic particle 101 and powder raw materials for the materials constituting the first layer 103 are supplied to a mixing vessel of a mechanical particle hybridizer, and impellers in the container are rotated to obtain the functional particle 100. The high-speed rotation of the impellers causes impact force, compressive force and shear force exerted over the individual inorganic particle 101 and the powder raw materials to achieve the hybridization of the powder over the surface of the inorganic particle 101 to create the first layer 103. Then, the particle having the first layer 103 formed thereon and the powder raw materials for the second layer 105 are employed to conduct the above-described processing to create the second layer 105 over the first layer 103.

While the processing for forming the first layer 103 or the second layer 105 is conducted so that any one or two component(s) of the epoxy resin, the curing agent thereof and the curing accelerator thereof is (are) contained in the first layer 103 and the other components (component) are (is) contained in the second layer 105. The raw materials for the first layer 103 and the second layer 105 may contain a plurality of raw materials other than the epoxy resin, the curing agent thereof, and the curing accelerator thereof, which are previously mixed to prepare a mixture, and such mixture may be employed to form the first or the second layer.

The rotating speed of the impeller may be, more specifically, circumferential velocity of 1 to 50 m/s, and in view of obtaining expected processing effect, may be equal to or higher than 7 m/s, and preferably equal to or higher than 10 m/s. In addition, in view of inhibiting heat generation in the processing and preventing excess pulverization, the rotating speed of the impeller may be, for example, equal to or lower than 35 m/s, and preferably equal to or lower than 25 m/s.

Here, the above-described mechanical particle hybridizer is an apparatus, which is capable of providing mechanical actions including compressive force, shear force and impact force for raw materials such as multiple types of powders to obtain fine particles, on which raw materials such as multiple types of powders are bound. Typical schemes for applying the mechanical actions include: a scheme for employing an apparatus having a rotor including one or a plurality of mixing impeller(s) and a mixing vessel having an inner circumference surface in proximity to a tip section of the mixing impeller and rotating the mixing impeller; or a scheme for rotating the mixing vessel while immobilizing or rotating the mixing impeller, or the like. The shape of the mixing impeller is not particularly limited as long as it is available to provide the mechanical actions, and typically includes oval shape, plate-like shape and the like. In addition, the mixing impeller may form an angle with the direction of the rotation. Further, the inner surface of the mixing vessel may be processed such as forming trenches or the like.

Typical mechanical particle hybridizer includes, for example: Hybridization System commercially available from Nara Machinery Co., Ltd.; Kryptron commercially available from Kawasaki Heavy Industries Co., Ltd.; Mechano Fusion System and Nobilta commercially available from Hosokawa Micron Co., Ltd.; Theta Composer commercially available from Tokuju Corporation; Mechanomill commercially available from Okada Seiko Co., Ltd.; and CF Mill commercially available from Ube Industries Ltd., though it is not limited thereto.

While the temperature in the container during the mixing process is configured according to the types of the raw materials, and may typically be, for example, equal to or higher than 5 degrees C. and equal to or lower than 50 degrees C., and in view of preventing melting of the organic compounds, may be equal to or lower than 40 degrees C., and preferably equal to or lower than 25 degrees C. However, alternative processing may also be conducted in the condition that the container is warmed to melt the organic compounds. Further, while the mixed time is defined according to the types of the raw materials, and may typically be, for example, equal to or longer than 30 seconds and equal to or shorter than 120 minutes, and in view of obtaining expected processing effect, may be equal to or longer than for 1 minute, and preferably equal to or longer than for 3 minutes, and in view of enhancing the productivity, may be equal to or shorter than for 90 minutes, and preferably equal to or shorter than for 60 minutes.

In view of forming the first layer 103 and the second layer 105 over the inorganic particle 101, respectively, with enhanced homogeneity, it is preferable to pulverize the solid components of the raw materials for the first layer 103 and the second layer 105 in advance by employing a jet mill and the like. The shape of the pulverized product may be arbitrarily selected, and typically crushed shape, substantially spherical, spherical and the like. In view of forming each of the first layer 103 and the second layer 105 with further stability, mean particle diameter of the raw materials for each of the first layer 103 and the second layer 105 may be, for example, equal to or smaller than the mean particle diameter of the inorganic particle 101, and preferably equal to or smaller than a half (½) of the mean particle diameter of the inorganic particle 101.

In addition to above, the analysis of the layer structures of the obtained functional particle 100 may be conducted by employing a scanning electron microscope, Raman spectroscopy and the like.

Next, the advantageous effect of the present embodiment will be described. In the functional particle 100, any one or two of the epoxy resin, the curing agent and the curing accelerator is (are) contained in the first layer 103, and the others are (is) contained in the second layer 105. Thus, the formulations of the respective functional particles 100 can be homogenized. Further, the functional particle 100 exhibiting homogenized formulation by respective particles can be obtained at enhanced production yield with improved stability. Thus, the respective components of the epoxy resin (A), the curing agent (B) and the curing accelerator (C) may be sustained on the inorganic particle 101 with improved stability. This can prevent the change of the composition due to the reaction of the components during the storage to present improved storage stability.

In addition, since the formulations of the respective functional particles 100 can be homogenized as described above, the functional particle 100 exhibiting homogenized formulation by respective particles may be employed as the semiconductor encapsulating resin composition to provide improved production stability of the semiconductor device.

In the following embodiments, the descriptions will be made by focusing on the difference from first embodiment.

### Second Embodiment

FIG. 1(b) is a cross-sectional view, showing a configuration of functional particle in the present embodiment.

While the basic configuration of functional particle 102 shown in FIG. 1(b) is similar to that of the functional particle 100 described in first embodiment (FIG. 1(a)), it is different that the second layer 105 has a plurality of layers.

More specifically, in the functional particle 102, the second layer 105 includes a lower layer 105b provided in contact with an upper side of the first layer 103 and an upper layer 105a provided in contact with an upper side of the lower layer 105b.

The first layer 103 contains any one component of the resin, the curing agent and the curing accelerator. In addition, in the second layer 105, the lower layer 105b contains one component of the resin, the curing agent and the cure accelerator, and does not contain the component contained in the first layer 103, and the upper layer 105a contains the component thereof, which is not contained in any of the first layer 103 and the lower layer 105b. For example, the configuration may be composed of the first layer 103 containing the resin, the lower layer 105b containing the curing agent and the upper layer 105a containing the curing accelerator, which are disposed in this sequence.

The functional particle 102 in the present embodiment is configured that the resin, the curing agent and the cure accelerator are disposed as distinct layers on the inorganic particle 101 by a predetermined sequence. This allows more effectively inhibiting the reaction between the components and deterioration of the quality during the storage.

In addition, a configuration containing both the curing agent and the curing accelerator in one of the first layer 103 and the second layer 105 and containing the epoxy resin in the other thereof, or a configuration containing both the epoxy resin and the curing agent in one of the first layer 103 and the second layer 105 and containing the curing accelerator in the other thereof may be employed to obtain the functional particle 102 exhibiting further enhanced storage stability.

### Third Embodiment

In the functional particle employed in the above-described embodiments, an interposing layer disposed between the first layer 103 and the second layer 105 for separating these layers may be provided. The following descriptions will be made in reference to the functional particle 100 of first embodiment.

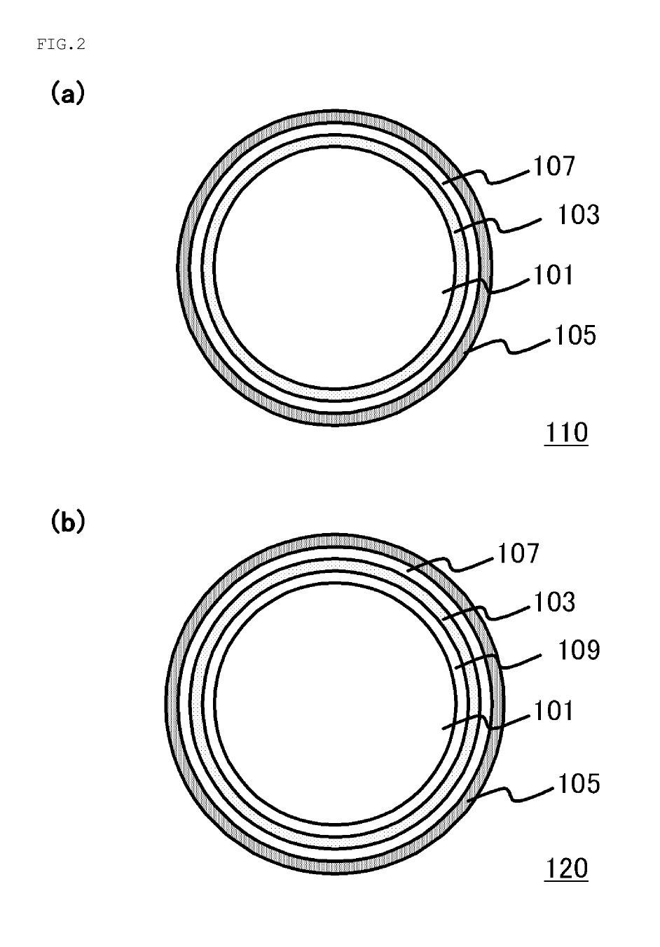

While the basic configuration of the functional particle 110 shown in FIG. 2(a) is similar to that of the functional particle 100 (FIG. 1(a)), it is different that an interposing layer 107 is further included. The first layer 103 is separated from the second layer 105 by the presence of the interposing layer 107. The presence of the interposing layer 107 avoids the contact between the first layer 103 and the second layer 105, so that the reaction of the resin contained in these layers with the curing agent and the curing accelerator can be further firmly inhibited. Thus, the change of the composition due to the reaction of the resin contained in these layers with the curing agent and the curing accelerator can be further firmly inhibited to provide the configuration exhibiting further enhanced storage stability.

While the constituent materials for the interposing layer 107 are not particularly limited, for example, one or more material(s) selected from a group consisting of metalhydroxide, coupling agent, mold releasing agent, ion trapping agent, coloring agent and fire retardant agent may be contained.

When the interposing layer 107 is configured to contain metalhydroxide such as aluminum hydroxide, magnesium hydroxide, calcium hydroxide, hydrotalcite and the like as a main constituent, the contact of the first layer 103 with the second layer 105 can be inhibited, and further, advantageous effects such as enhanced fire retardancy and enhanced corrosion resistance are exhibited.

When the interposing layer 107 is configured to contain a coupling agent such as epoxysilane coupling agent, aminosilane coupling agent and the like as a main constituent, this can effectively interact with the first layer 103 and the second layer 105, so as to contribute to reducing the viscosity in the molding process. In addition, when it is coated with a low stress component, the contact of the first layer 103 with the second layer 105 can be inhibited, and also, the function as the low stress material can be more easily exhibited, so that the reliability for the semiconductor device formed therewith can be further improved.

In addition, the interposing layer 107 may be configured of a low stress component such as silicone rubbers such as silicone oil, low melting point silicone rubber and the like, or synthetic rubbers such as low melting point synthetic rubber and the like as a main constituent. This allows effectively interacting with the first layer 103 and the second layer 105 to easily be penetrated between the first layer 103 and the second layer 105, such that the contact of the first layer 103 with the second layer 105 can be inhibited, and also, the function as the low stress material can be more easily exhibited, so that the reliability for the semiconductor device formed therewith is further improved. Alternatively, the interposing layer 107 may be configured of a pigment (coloring agent) such as carbon black and the like, or an ion trapping agent such as hydrotalcite and the like, as a main constituent. Alternatively, the interposing layer 107 may be configured of, for example, a fire retardant agent. In addition to the above-described metalhydroxide, phosphorus-based, silicone-based, organometallic salt-based materials may be employed as a fire retardant agent.

Alternatively, the interposing layer 107 may be configured of a wax-type material as a main constituent, and typical wax-type material includes, more specifically nature wax such as carnauba wax and the like, and synthetics wax such as polyethylene wax and the like. The interposing layer 107 is configured of the wax-type material, so that the wax-type material melts in the molding process by the above-described processing to easily coat the entire surface of the first layer 103, and therefore the contact of the first layer 103 with the second layer 105 can be inhibited, and further, advantageous effect such as enhanced mold-releasability is exhibited. Further, since the wax-type material melts during the processing by the above-described processing to easily coat the entire surface of the first layer 103, it is more easy to form the first layer 103 uniformity over the entire surface of the second layer 105.

Further, the interposing layer 107 may, for example, contain one, two or more inorganic material(s) selected from the group consisting of silica, alumina and silicon nitride. Further, other than the above-described materials, there is no objection for the interposing layer to contain a component that is substantially inactive with the component abutting with the interposing layer. This allows reducing the coefficient of linear expansion for the semiconductor device formed therewith, and therefore the reliability in the use as a sealant for the semiconductor device is further improved.

### Fourth Embodiment

In the functional particle employed in the above-described embodiments, a third layer may further be provided between the inorganic particle 101 and the first layer 103. The following descriptions will be made in reference to the functional particle 110 of third embodiment.

FIG. 2(b) is a cross-sectional view, showing a configuration of particle having a third layer 109. While the basic configuration of functional particle 120 shown in FIG. 2(b) is similar to that of the functional particle 110 shown in FIG. 2(a), it is different that the third layer 109 is further provided so as to be in contact with the inorganic particle 101.

While the materials for the third layer 109 are not particularly limited, for example, one or more material(s) selected from a group consisting of metalhydroxide, coupling agent, mold releasing agent, ion trapping agent, coloring agent and fire retardant agent may be contained.

Further, the third layer 109 may be configured to contain, for example, an inorganic material that is different from the inorganic particle 101 as a main constituent. Typical inorganic material that is different from the inorganic particle 101 may include, for example: metalhydroxide such as aluminum hydroxide, magnesium hydroxide, calcium hydroxide, hydrotalcite and the like; talc; and clay.

Further, the third layer 109 may contain a coupling agent such as epoxysilane coupling agent, aminosilane coupling agent and the like as a main constituent to exhibit improved stiffening effect. Alternatively, the third layer 109 may be configured of, for example, a fire retardant agent. In addition to the above-described metalhydroxide, phosphorus-based, silicone-based, organometallic salt-based materials may be employed as a fire retardant agent. Further, the materials exemplified as the materials for the interposing layer 107 in second embodiment may be employed for the third layer 109.

Further, specific examples of combinations of the main constituents for the inorganic particle 101 and the third layer 109 are as follows. A combination of, the inorganic particle 101: silica and the third layer 109: metalhydroxide, and a combination of, the inorganic particle 101: alumina and the third layer 109: silicone.

Any of the functional particles described in the above-described embodiments may be preferably employed as, for example, filler. Further, the filler in the present embodiment may be composed of the functional particle in the present embodiment described above.

Typical configuration of filler may be, for instant, the following examples. The inorganic particle 101: spherical silica, the first layer 103: curing agent for epoxy resin, and the second layer 105: epoxy resin. This configuration is preferable for, for example, electronic component applications such as semiconductor encapsulating materials and the like. The inorganic particle 101: spherical silica, the first layer 103: curing agent and curing accelerator for epoxy resin, and the second layer 105: epoxy resin. This configuration is preferable for, for example, electronic component applications such as semiconductor encapsulating materials and the like. The inorganic particle 101: glass fiber, the first layer 103: curing agent for phenolic resin such as hexamethylene tetramine and the like, and the second layer 105: phenolic resin such as novolac type phenolic resin and the like. This configuration is preferable for, for example, for automotive molding materials. The inorganic particle 101: crystalline silica and aluminum hydroxide, the first layer 103: curing agent for epoxy resin, and the second layer 105: epoxy resin. This configuration is preferable for, for example, insulator materials for electronic components.

### Fifth Embodiment

The present embodiment relates to a resin composition containing a filler, which is composed of the functional particle described in the above-described embodiments. The resin composition in the present embodiment contains the functional particle described in the above-described embodiments, and known components and the like known in the fields of semiconductor encapsulating resin compositions, automotive molding materials and insulator materials for electronic components, which are used as required. Then, it is configured to contain the functional particle described in the above-described embodiments as the filler uniformly dispersed in the composition. In the filler contained in the composition, a portion of the first layer 103 and the second layer 105 may exhibit changing their composition, or may disappear.

While the content of the inorganic particle 101 in the resin composition is not particularly limited, it is preferable to be equal to or larger than 40% mass and equal to or smaller than 96% mass over the whole resin composition, and more preferably equal to or larger than 50% mass and equal to or smaller than 92% mass. Further, in the case of the semiconductor encapsulating resin compositions it is preferable to be equal to or larger than 70% mass and equal to or smaller than 96% mass over the whole resin composition, and more preferably equal to or larger than 85% mass and equal to or smaller than 92% mass. The content within the above-described range allows further effectively inhibiting the deterioration in the solder resistance and/or the deterioration in the flowability.

While the content of the resin in the resin composition is not particularly limited, it is preferable to be equal to or larger than 2% mass and equal to or smaller than 50% mass over the whole resin composition, and more preferably equal to or larger than 2.5% mass and equal to or smaller than 40% mass, and particularly in the case of the semiconductor encapsulating resin compositions, it is preferable to be equal to or larger than 2% mass and equal to or smaller than 15% mass over the whole resin composition, and more preferably equal to or larger than 2.5% mass and equal to or smaller than 8% mass. This allows further effectively inhibiting the deterioration in the solder resistance and/or the deterioration in the flowability.

Further, while the content of the curing agent in the resin composition is not particularly limited, it is preferable to be equal to or larger than 2% mass and equal to or smaller than 30% mass over the whole resin composition, and more preferably equal to or larger than 2% mass and equal to or smaller than 20% mass, and particularly in the case of the semiconductor encapsulating resin compositions, it is preferable to be equal to or larger than 1% mass and equal to or smaller than 15% mass over the whole resin composition, and more preferably equal to or larger than 2% mass and equal to or smaller than 7% mass. This allows further effectively inhibiting the deterioration in the solder resistance and/or the deterioration in the flowability.

Further, the content of the curing accelerator in the resin composition is, for example, equal to or larger than 0.1% mass of the whole resin composition. This allows further effectively inhibiting the deterioration in the curability of the composition. In addition, the content of the curing accelerator is, for example, equal to or smaller than 1% mass of the whole resin composition. This allows further effectively inhibiting the deterioration in the flowability of the composition.

In addition, in the resin compositions in the present embodiment, various types of known components in the field of the semiconductor encapsulating resin composition such as coupling agent, mold releasing agent, ion trapping agent, coloring agent and fire retardant agent and the like may be blended as the composition containing filler in addition to the functional particle according to the present invention, according to the applications. More specifically, various types of additives such as: a curable resin; a filler other than the functional particle 100; a coupling agent; a coloring agent such as carbon black, colcothar and the like; a low stress component such as silicone oil, silicone rubber and the like; a demolding material such as nature wax, synthetic wax, higher fatty acid and metal salts thereof, or paraffin and the like; an inorganic ion exchanger such as hydrate of bismuth oxide and the like; a fire retardant agent such as aluminum hydroxide, magnesium hydroxide, calcium hydroxide, hydrotalcite, antimony oxide, zinc borate and the like; antioxidant; and the like may be suitably blended in the composition.

In the present embodiment, the shape of the resin composition may be suitably selected according to the forming method in the process for forming the composition. For example, the resin composition of the present embodiment may be in the form of the granules or the pellets for the compression molding. Alternatively, the resin composition of the present embodiment may be in the form of the tablets for the transfer molding.

Among these, the resin composition of the present embodiment may be configured in the form of the granules or the pellets composed of the functional particle described in the above embodiments, so that the agglomeration of particles is inhibited to improve the flowability of the power and reduce the adhesiveness, and therefore an adhesion into the transport path is avoided to provide reduced possibility to cause an obstacle in the transportation, and thus, the trouble such as the stagnant residence in the transportation of the resin composition of the present embodiment to the metallic mold can be firmly inhibited. Further, the loading level in the molding can be improved. Therefore, the production yield for obtaining the molded product by the compression molding can be improved.

In view of improving the handling facility during the transportation or measurement and the like and enhancing the storage stability of the resin composition in the resin composition in the form of the granules, the proportion of fine powder of smaller than 1 μm over the entire filler in the particle size distribution measured by employing screen sizing using Japanese Industrial Standards (JIS) standard sieves may be, for example, equal to or lower than 5% mass, and preferably equal to or lower than 3% mass.

Further, in view of reducing the proportion of the fine powder in the granular resin composition, the particle size d10, which is defined as the size for providing the cumulative frequency of 10% measured by using a laser diffraction particle size distribution measuring device, may be, for example, equal to or larger than 3 μm, and preferably equal to or larger than 5 μm. In addition to above, the upper limit of d10 is not particularly limited, and may be defined according to the mean particle diameter and the like of the base particle, which is determined in consideration of the gate size of the metallic mold and the like, and for example, may be equal to or smaller than 10 μm.

The resin composition of the present embodiment may be preferably employed as, for example, the resin composition for the electronic component, the automotive resin composition and the powder paint.

Next, the production process for the resin composition of the present embodiment will be described. The resin composition of the present embodiment can be obtained by mixing the filler composed of the functional particle as described in the above embodiment and other additives as required by using a mixer at an ambient temperature. Further, as far as the advantageous effect of the present invention is not deteriorated, a roll, kneading machine such as a kneader and the like or an extruder and the like may be employed to melt and knead the composition, and after cooling, the compound may be pulverized.

The resultant resin composition is molded to obtain the molded product. In order to produce the molded product, suitable molding process such as transfer molding, compression molding, injection molding and the like is utilized to carry out the cure and the molding. In the molding process, the composition or the morphology of the whole or a portion of the first layer 103 and the second layer 105 may be changed. For example, it may be permitted that the resin and the curing agent contained in the first layer 103 and the second layer 105 are cured by the molding to cause that the inorganic particle 101 derived from the filler remains in the cured product.

The resin composition for the electronic component in the present embodiment is molded to obtain the electronic component. For example, the resin composition for the electronic component in the present embodiment is used for encapsulating the semiconductor element to obtain the semiconductor device. Further, the process for producing the semiconductor device in the present embodiment includes the step for encapsulating the semiconductor element with the semiconductor encapsulating resin composition by employing, for example, compression molding or transfer molding, or injection molding.

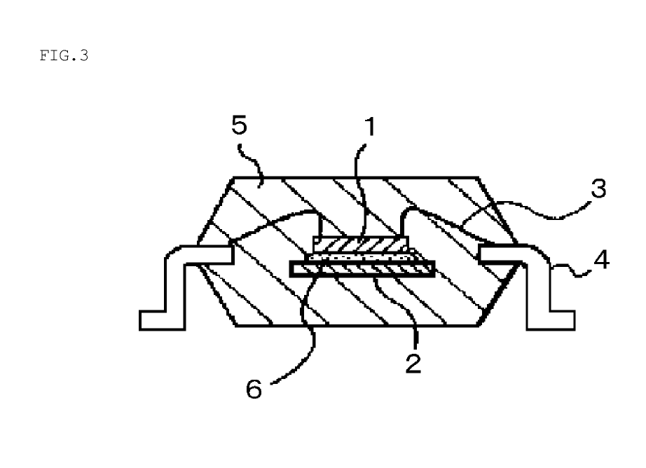

FIG. 3 is a cross-sectional view, showing a configuration of a semiconductor device employing the resin composition for the electronic component in the present embodiment. In the semiconductor device shown in FIG. 3, a semiconductor element 1 is fixed on a die pad 2 through a cured product of a die bond material 6. An electrode pad of the semiconductor element 1 is connected to a lead frame 4 through a gold wire 3. The semiconductor element 1 is encapsulated by a cured product 5 of an encapsulating material. The cured product 5 of the encapsulating material is a cured product of the resin composition for the electronic component of the present embodiment as described above.

According to first to fifth embodiments, a layer containing the epoxy resin, the curing agent and the curing accelerator for the resin may be provided as the layer covering the base particle composed of the inorganic material to achieve the stable retention of these components over the base particle at the predetermined formulation.

### Sixth Embodiment

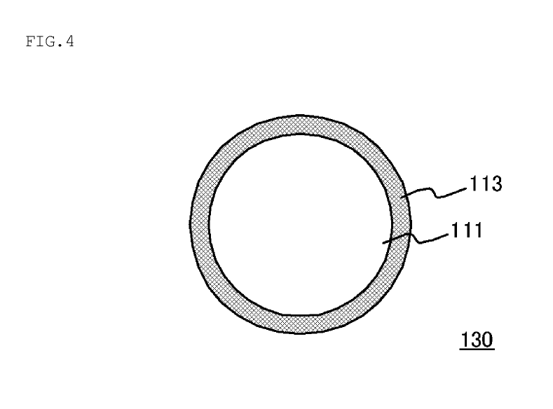

FIG. 4 is a cross-sectional view, showing a configuration of a coated particle in the present embodiment. A coated particle 130 shown in FIG. 4 is composed of an inorganic particle 111 serving as a base particle composed of an inorganic material, and a first layer 113 for coating the inorganic particle 111. The first layer 113 may be constituted with various types of raw materials that constitutes the resin composition for the electronic component, and minimum and essential constituent elements thereof are: a first coated particle having the first layer 113 composed of a resin; and a second coated particle having the first layer composed of a curing agent for the resin, and these coated particles constitute the functional particle group. In addition to above, the first layer 113 may contain a plurality of components.

In the example of FIG. 4, the first layer 113 is in contact with the surface of the inorganic particle 111, and covers the entire surface of the inorganic particle 111. In addition, the first layer 113 is provided to have uniform thicknesses in a cross-sectional view as a preferable aspect.

While FIG. 4 shows the exemplary implementation having smooth interface between the inorganic particle 111 and the first layer 113, the interface may alternatively have irregularity.

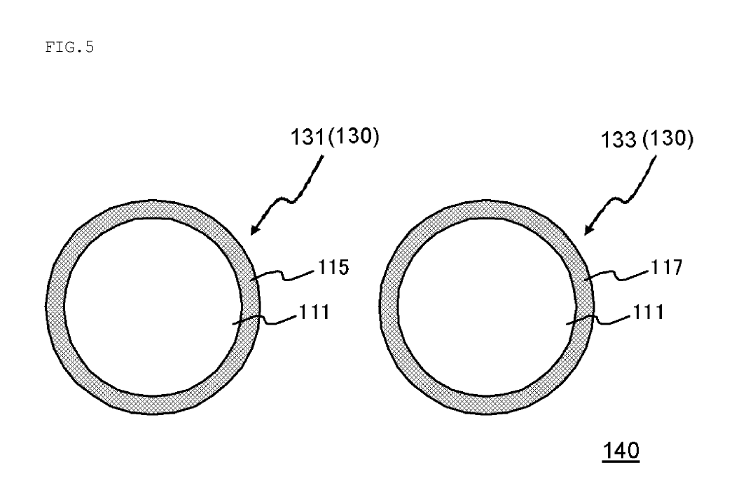

FIG. 5 is a cross-sectional view, showing a configuration of the functional particle group in the present embodiment. The functional particle group 140 shown in FIG. 5 contains the first particle (first coated particle) 131 configured of the inorganic particle 111 coated with the resin, and the second particle (second coated particle) 133 configured of the inorganic particle 111 coated with the curing agent of the resin. A resin layer 115 of the first particle 131 and a curing agent layer 117 of the second particle 133 correspond to the first layer 113 of the coated particle 130 shown in FIG. 4.

In the first layer in the first coated particle, the thickness of the layer to provide coating with the resin (resin layer 115 of FIG. 5) is not particularly limited, as long as the thickness satisfies the required blending amount for inducing the reaction with the curing agent, and for example, may be equal to or larger than 5 nm, and preferably equal to or larger than 50 nm, and on the other hand, in view of providing further improved productivity, for example, may be equal to or smaller than 50 μm, and preferably equal to or smaller than 5 μm.

Further, in the first layer in the second coated particle, the thickness of the layer to provide coating with the curing agent (curing agent layer 117 of FIG. 5) is not particularly limited, as long as the thickness satisfies the required blending amount for inducing the reaction with the resin, and for example, may be equal to or larger than 5 nm, and preferably equal to or larger than 50 nm, and on the other hand, in view of providing further improved productivity, for example, may be equal to or smaller than 50 μm, and preferably equal to or smaller than 5 μm.

The materials constituting each of the layers will be described in reference to specific examples.

Typical material for the inorganic particle 111 includes, for example: silica powders such as fused crushed silica powder, fused spherical silica powder, crystal silica powder, secondary agglomerated silica powder and the like; alumina; titanium white; aluminum hydroxide; talc; clay; mica; and glass fiber.

Among these, in view of the installation reliability of the electronic component and the semiconductor device, it is preferable to employ a spherical particle composed of an inorganic material of one, two or more material(s) selected from the group consisting of silica, alumina and silicon nitride for the inorganic particle 111. In these inorganic materials, silica is particularly preferable. Alternatively, in view of the mechanical strength, it is preferable to employ a fibrous particle composed of a fiber material such as a glass fiber and the like for the inorganic particle 111. Alternatively, the inorganic particle 111 may be a particle obtained by processing a nonwoven fabric such as a glass nonwoven fabric and the like into particle-shape.

In addition, the particle shape of the inorganic particle 111 is not particularly limited, and for example: crushed shape; spherical shape such as substantially spherical, spherical and the like; fibrous shape; probe shape and the like. Mean particle diameter in the case that the inorganic particle 111 is a spherical particle may be, in view of inhibiting the agglomeration of particles, for example equal to or larger than 1 μm, and preferably equal to or larger than 10 μm. In addition, from the viewpoint of the smoothness, the particle size of the inorganic particle 111 may be for example, equal to or smaller than 100 μm, and preferably equal to or smaller than 50 μm.

In addition to above, a combination of particles having different sizes may be employed for the inorganic particle 111. For example, when the inorganic particle 111 is employed for a filler employed in a sealant of an electronic component, the use of the combination of the particles having different sizes provides enhanced flowability, such that higher filler loading can be achieved to provide further improved package reliability such as solder thermal resistance and the like. In this case, the inorganic particle for the use in combination with the inorganic particle having the above-mentioned mean particle diameter may have the mean particle diameter of, for example, equal to or larger than 50 nm and preferably equal to or larger than 200 nm, in view of inhibiting the agglomeration of the particles. In view of enhancing the flowability, it may be, for example, equal to or smaller than 2.5 μm, and preferably equal to or smaller than 1 μm.

Next, the resin and the curing agent for the resin will be described. The resin and the curing agent constitute the resin layer 115 and the curing agent layer 117, respectively. Typical materials for the respective resin and curing agent include, for example, the materials exemplified in first embodiment.

For example, curable resins may be employed for the resin. Typical curable resin may include the following thermosetting resins. For example, phenolic resins, epoxy resins, cyanate ester resins, urea resins, melamine resins, unsaturated polyester resins, bismaleimide resins, polyurethane resins, diallyphthalate resins silicone resins, resins having benzoxazin ring and the like, may be exemplified.

Typical phenolic resin includes, for example: novolac type phenolic resins such as phenol novolac resin, cresol novolac resin, bisphenol A based novolac resin and the like; methylol type resol resins; dimethylene ether type resol resins; and resol type phenolic resins such as oil-modified resol phenolic resins modified with tung oil, flaxseed oil, walnut oil and the like. One of these may be employed alone, or a combination of two or more of these may also be employed.

The epoxy resin generally includes whole of monomer, oligomer, and polymer, having two or more epoxy groups in a single molecule, and the molecular weight and the molecular structure thereof are not particularly limited. The epoxy resin typically includes, for example: difunctionalized or crystalline epoxy resins such as biphenyl type epoxy resin, bisphenol A based epoxy resin, bisphenol F type epoxy resin, stilbene type epoxy resin, hydroquinone type epoxy resin and the like; novolac type epoxy resins such as cresol novolac type epoxy resin, phenol novolac type epoxy resin, naphthol novolac type epoxy resin and the like; phenol aralkyl type epoxy resins such as phenylene skeleton-containing phenol aralkyl type epoxy resin, biphenylene skeleton-containing phenol aralkyl type epoxy resin, phenylene skeleton-containing naphthol aralkyl type epoxy resin and the like; trifunctional type epoxy resins such as triphenolmethane type epoxy resin and alkyl-modified triphenolmethane type epoxy resin and the like; modified phenol-type epoxy resins such as dicyclopenta diene-modified phenol type epoxy resin, terpene-modified phenol type epoxy resin and the like; and heteroring-containing epoxy resins such as triazine nucleus-containing epoxy resin and the like. One of these may be employed alone, or a combination of two or more of these may also be employed.

When the functional particle group 140 is employed for the filler employed in the sealant of the electronic component, it is preferable in view of providing improved package reliability to employ, for example: phenol novolac type epoxy resin, cresol novolac type epoxy resin and the like; biphenyl type epoxy resins; phenol aralkyl type epoxy resins such as phenylene skeleton-containing phenol aralkyl type epoxy resin, biphenylene skeleton-containing phenol aralkyl type (or biphenyl aralkyl type) epoxy resin, phenylene skeleton-containing naphthol aralkyl type epoxy resin and the like; trifunctional type epoxy resins such as triphenol methane type epoxy resin and alkyl-modified triphenolmethane type epoxy resin and the like; modified phenol type epoxy resins such as dicyclopenta diene-modified phenol type epoxy resin, terpene-modified phenol type epoxy resin and the like; heteroring-containing epoxy resins such as triazine nucleus-containing epoxy resin and the like; and arylalkylene type epoxy resin.

As typical cyanate ester resin, for example, a compound obtained by reacting a halogen cyanide compound with a phenol, or a product obtained by a pre-polymerization thereof by heating or the like, may be employed. Specific conformation may include, for example, novolac type cyanate resins, and bisphenol type cyanate resins and the like, such as bisphenol A type cyanate resin, bisphenol E type cyanate resin, tetramethyl bisphenol F type cyanate resin and the like. One of these may be employed alone, or a combination of two or more of these may also be employed.

The curing agent is suitably selected according to type of the resin. For example, when the first layer in the first coated particle (resin layer 115) contains the epoxy resin, the available curing agent for such epoxy may be any agent as long as it reacts with the epoxy resin to induce the cure thereof, and the agents known by a person having ordinary skills in the art may be employed, and typically for example: aliphatic polyamines such as diethylenetriamine (DETA), triethylenetetramine (TETA), metaxylene diamine (MXDA) and the like; aromatic polyamines such as diaminodiphenyl methane (DDM), m-phenylenediamine (MPDA), diaminodiphenylsulphone (DDS) and the like, and additionally polyamine compounds containing dicyandiamide (DICY), organic acid dihydrazide and the like; alicyclic acid anhydride such as hexahydrophthalic anhydride (HHPA), methyltetrahydrophthalic anhydride (MTHPA) and the like; acid anhydrides containing aromatic acid anhydride such as trimellitic anhydride (TMA), pyromellitic dianhydride (PMDA), benzophenone tetracarboxylic acid (BTDA) and the like; polyphenol compound such as novolac type phenolic resin, and phenol aralkyl type epoxy resins such as phenylene skeleton-containing phenol aralkyl resin, biphenylene skeleton-containing phenol aralkyl (or biphenyl aralkyl) resin, phenylene skeleton-containing naphthol aralkyl resin and the like, and bisphenol compounds such as bisphenol A and the like; poly mercaptan compounds such as polysulphide, thioester, thioether and the like; isocyanate compounds such as isocyanate prepolymer, blocked isocyanate and the like; organic acids such as carboxylic acid-containing polyester resin and the like; tertiaryamine compounds such as benzil dimethylamine (BDMA), 2,4,6-tridimethylaminomethyl phenol (DMP-30) and the like; imidazole compounds such as 2-methyl imidazole, 2-ethyl-4-methyl imidazole (EMI24) and the like; Lewis acids such as boron trifluoride (BF₃) complex and the like; phenolic resins such as novolac type phenolic resin, resol type phenolic resin and the like; urea resins such as methylol group-containing urea resin; and melamine resins such as methylol group-containing melamine resin and the like. Among these curing agents, it is particularly preferable to employ a phenolic resin. The phenolic resin employed in the present embodiment generally includes whole of monomer, oligomer, and polymer, having two or more phenolic hydroxyl groups in a single molecule, and the molecular weight and the molecular structure thereof are not particularly limited, and typically includes for example, phenol novolac resin, cresol novolac resin, dicyclopenta diene-modified phenolic resin, terpene-modified phenolic resin, triphenolmethane type resin phenolaralkyl resin (having phenylene skeleton, biphenylene skeleton and the like) and the like, and one of these may be employed alone, or a combination of two or more of these may also be employed.

Next, the production process for the coated particle 130 constituting the functional particle group will be described. The coated particle 130 may be obtained by conducting a step for forming the first layer 113 on the surface of the inorganic particle 111.

More specifically, the inorganic particle 111 and powder raw materials for the materials constituting the first layer 113 are supplied to a mixing vessel of a mechanical particle hybridizer, and impellers in the container are rotated to obtain it. The high-speed rotation of the impellers causes impact force, compressive force and shear force exerted over the individual inorganic particle 11 and the powder raw materials to achieve the hybridization of the powder over the surface of the inorganic particle 111 to create the first layer 113. Then, the particle having the first layer 113 formed thereon and the powder raw materials for the second layer 115 are employed to conduct the above-described processing to create the second layer 115 over the first layer 113. In addition to above, when the processing for forming the first layer 113, a plurality of raw materials containing at least one of the resin and the curing agent may be previously mixed, and such mixture may be employed to form the first layer 113. The rotating speed of the impeller may be, more specifically, circumferential velocity of 1 to 50 m/s, and in view of obtaining expected processing effect, may be equal to or higher than 7 m/s, and preferably equal to or higher than 10 m/s. In addition, in view of inhibiting heat generation in the processing and preventing excess pulverization, the rotating speed of the impeller may be, for example, equal to or lower than 35 m/s, and preferably equal to or lower than 25 m/s.

Here, the above-described mechanical particle hybridizer is an apparatus, which is capable of providing mechanical actions including compressive force, shear force and impact force for raw materials such as multiple types of powders to obtain fine particles, on which raw materials such as multiple types of powders are bound. Typical schemes for applying the mechanical actions include: a scheme for employing an apparatus having a rotor including one or a plurality of mixing impeller(s) and a mixing vessel having an inner circumference surface in proximity to a tip section of the mixing impeller and rotating the mixing impeller; or a scheme for rotating the mixing vessel while immobilizing or rotating the mixing impeller, or the like. The shape of the mixing impeller is not particularly limited as long as it is available to provide the mechanical actions, and typically includes oval shape, plate-like shape and the like. In addition, the mixing impeller may form an angle with the direction of the rotation. Further, the inner surface of the mixing vessel may be processed such as forming trenches or the like.

Typical mechanical particle hybridizer includes, for example: Hybridization System commercially available from Nara Machinery Co., Ltd.; Kryptron commercially available from Kawasaki Heavy Industries Co., Ltd.; Mechano Fusion System and Nobilta commercially available from Hosokawa Micron Co., Ltd.; Theta Composer commercially available from Tokuju Corporation; Mechanomill commercially available from Okada Seiko Co., Ltd.; and CF Mill commercially available from Ube Industries Ltd., though it is not limited thereto.

While the temperature in the container during the mixing process is configured according to the types of the raw materials, and may typically be, for example, equal to or higher than 5 degrees C. and equal to or lower than 50 degrees C., and in view of preventing melting of the organic compounds, may be equal to or lower than 40 degrees C., and preferably equal to or lower than 25 degrees C. However, alternative processing may also be conducted in the condition that the container is warmed to melt the organic compounds. While the mixed time is defined according to the types of the raw materials, and may typically be, for example, equal to or longer than 30 seconds and equal to or shorter than 120 minutes, and in view of obtaining expected processing effect, may be equal to or longer than for 1 minute, and preferably equal to or longer than for 3 minutes, and in view of enhancing the productivity, may be equal to or shorter than for 90 minutes, and preferably equal to or shorter than for 60 minutes.

In addition to above, the analysis of the layer structures of the obtained coated particle 130 may be conducted by employing a scanning electron microscope, Raman spectroscopy and the like.

Further, in the present embodiment, in view of forming the first layer 113 over the inorganic particle 111 with enhanced homogeneity, it is preferable to pulverize the solid components of the raw materials for the first layer 113 in advance by employing a jet mill and the like, as described above in first embodiment. The shape may be arbitrarily selected, and typically crushed shape, substantially spherical, spherical and the like. In view of forming each of the first layer 113 with further stability, mean particle diameter of the raw materials for each of the layers may be, for example, equal to or smaller than the mean particle diameter of the inorganic particle, and preferably equal to or smaller than a half (½) of the mean particle diameter of the inorganic particle.

Next, the advantageous effect of the present embodiment will be described. The coated particle 130 of the present embodiment (the functional particle group 140 in FIG. 5) is composed of the first particle 131 presented by the inorganic particle 111 coated with the resin and the second particle 133 presented by the inorganic particle 111 coated with the curing agent for the above-described resin. Thus, the resin or the curing agent and the curing accelerator can be stably retained on the base particle, respectively, at the predetermined formulation. Further, the blending formulations of the respective particles of the first particle 131 and the second particle 133 can be homogenized. Further, since the functional particle group 140 is composed of the first particle 131 and the second particle 133, the segregation of the respective coated particles caused due to the difference in the particle size or the difference in the specific gravity in the mixing operation or the like may be inhibited.

As described above, according to the present embodiment, the coated particle 130 having homogenized formulation and having a coating containing each of the constituent element as the first layer is mixed according to a prescription, so that the functional particle group, which hardly causes the segregation of the raw materials, can be obtained at enhanced production yield with improved stability. Further, the resin and the curing agent are provided to the coatings on the different the base particles to obtain the functional particle group exhibiting improved storage stability.

In addition to above, when the first layer is formed, a plurality of raw materials according to a combination of raw materials, which does not deteriorate the advantageous effects of the present embodiment, are previously mixed and such mixture is employed to provide the first layer containing any one of the resin and the curing agent.

### Seventh Embodiment

The particle and the functional particle group employed thereof shown in FIGS. 4 and 5 may include a third coated particle having the first layer 113 composed of a third component other than the aforementioned resin and curing agent in addition to the first coated particle having the first layer 113 composed of the resin and the second coated particle having the first layer 113 composed of the curing agent of the aforementioned resin. The third coated particle may exist among the first coated particle and the second coated particle allows a change of the level of the contact between the first coated particle and the second coated particle, and further, the aforementioned third component may be suitably selected to further provide the reaction of the resin with the curing agent. Thus, the change of the composition by the reaction of the resin with the curing agent is further firmly inhibited to allow providing the configuration with further enhanced storage stability.

The inorganic particle 111 of the third coated particle is composed of, for example, the materials same as the inorganic particle 111 of the first and the second coated particles.

While the constituent components of the first layer 113 of the third coated particle are not particularly limited, the curing accelerators (curing catalysts) for acting with the curing agents for the resin constituting the first layer 113 of the first coated particle and the resin constituting the first layer 113 of the second coated particle may be contained. The curing catalyst may be suitably selected according to the types of the resin and the curing agent, and may be compounds that are capable of acting with the resin and the curing agent and accelerates the curing reaction. For example, when the first layer 113 contains the epoxy resin, the curing catalyst for such resin may be compounds that are capable of reacting with the resin and the curing agent and accelerates the curing reaction. Typically, such compounds may include, for example, 1,8-diazabicyclo(5,4,0)undecene-7 (DBU), triphenylphosphine, 2-methyl imidazole, tetraphenylphosphonium tetraphenyl borate and the like. One of these may be employed alone, or a mixture of two or more of these may also be employed. Further, the compounds exemplified as the curing accelerator in first embodiment may be employed for the curing catalyst.

The first layer 113 of the third coated particle may contain, for example, one or more material(s) selected from a group consisting of metalhydroxide, coupling agent, mold releasing agent, ion trapping agent, coloring agent and fire retardant agent.

The first layer 113 of the third coated particle is configured to contain metalhydroxide such as aluminum hydroxide, magnesium hydroxide, calcium hydroxide, hydrotalcite and the like as a main constituent, so that the contact of the first layer 113 with the second layer 115 can be inhibited, and further, advantageous effects such as enhanced fire retardancy and enhanced corrosion resistance are exhibited. Further, the first layer 113 of the third coated particle is configured to contain a coupling agent such as epoxysilane coupling agent, aminosilane coupling agent and the like as a main constituent, this can effectively interact with the first particle 131 and the second particle 121, so as to contribute to reducing the viscosity in the molding process. Further, improved stiffening effect may be exhibited.

Further, the first layer 113 of the third coated particle may be configured to contain low stress components as main constituents, which includes silicone rubbers such as silicone oil, low melting point silicone rubber and the like, and synthetic rubbers such as low melting point synthetic rubber and the like. This allows effectively interacting with the first and the second coated particles to easily be penetrated between the first and the second coated particles, such that the contact of the first coated particle with the second coated particles can be inhibited, and also, the function as the low stress material can be more easily exhibited, so that the reliability for the sealant of the semiconductor device formed therewith is further improved. Further, the first layer 113 of the third coated particle may be configured of a pigment (coloring agent) such as carbon black, an ion trapping agent such as hydrotalcite and the like as a main constituent. Further, the first layer 113 of the third coated particle may be configured of, for example, a fire retardant agent. In addition to the above-described metalhydroxide, phosphorus-based, silicone-based, organometallic salt-based materials may be employed as a fire retardant agent.

Further, the first layer 113 of the third coated particle may be configured of a wax-type material as a main constituent. Typical wax-type material includes, more specifically nature wax such as carnauba wax and the like, and synthetics wax such as polyethylene wax and the like. The first layer 113 of the third coated particle is configured of the wax-type material, so that the wax-type material in the above-described functional particle group melts in the molding process by the above-described processing to easily penetrate between the first and the second coated particles, and therefore the contact of the first and the second coated particles can be inhibited, and further, advantageous effect such as enhanced mold-releasability is exhibited. Further, since the wax-type material melts during the processing by the above-described processing to easily coat the entire surface of the first layer 113 of the third coated particle, it is more easy to form the first layer 113 of the third coated particle uniformity over the entire surface of the inorganic particle 111.

Further, the first layer 113 of the third coated particle may contain one or more inorganic material(s) selected from the group consisting of silica, alumina and silicon nitride. Further, the first layer 113 of the third coated particle may be formed by coating with a component containing a liquid raw material.

The functional particle group described in the above-described embodiment is preferably employed as, for example, filler. Further, the filler in the present embodiment is composed of the above-described functional particle group according to the present invention.

Typical configuration of filler may be, for instant, the following examples. The inorganic particle 111: spherical silica, the first layer 113 of the first coated particle: curing agent for epoxy resin, and the first layer 113 of the second coated particle: epoxy resin. This configuration is preferable for, for example, electronic component applications such as semiconductor encapsulating materials and the like. The inorganic particle 111: glass fiber, the first layer 113 of the first coated particle: curing agent for phenolic resin such as hexamethylene tetramine and the like, and the first layer 113 of the second coated particle: phenolic resin such as novolac type phenolic resin and the like. This configuration is preferable for, for example, for automotive molding materials. The inorganic particle 111: crystalline silica and aluminum hydroxide, the first layer 113 of the first coated particle: curing agent for epoxy resin, and the first layer 113 of the second coated particle: epoxy resin. This configuration is preferable for, for example, insulator materials for electronic components.

### Eighth Embodiment

The present embodiment relates to a resin composition containing filler composed of the functional particle group described in the above-described embodiment. This resin composition is a composition containing the functional particle group described in the above-described embodiment and a component and the like known in the field of the semiconductor encapsulating resin composition used as required, and is configured of the functional particle group described in the above-described embodiment dispersed in the composition. In filler contained in the composition, a portion of the first layer 113 may exhibit changing their composition, or may disappear.

Further, the content of the inorganic particle in the composition serving as filler is not particularly limited, it is preferable to be equal to or larger than 40% mass and equal to or smaller than 96% mass over the whole composition, and more preferably equal to or larger than 50% mass and equal to or smaller than 92% mass. Further, in the case of the semiconductor encapsulating resin compositions it is preferable to be equal to or larger than 70% mass and equal to or smaller than 96% mass over the whole resin composition, and more preferably equal to or larger than 85% mass and equal to or smaller than 92% mass. The content within the above-described range allows further effectively inhibiting the deterioration in the solder resistance and/or the deterioration in the flowability.

While the content of the curable resin in the composition serving as the filler is not particularly limited, it is preferable to be equal to or larger than 2% mass and equal to or smaller than 50% mass over the whole resin composition, and more preferably equal to or larger than 2.5% mass and equal to or smaller than 40% mass, and particularly in the case of the semiconductor encapsulating resin compositions, it is preferable to be equal to or larger than 2% mass and equal to or smaller than 15% mass over the whole composition, and more preferably equal to or larger than 2.5% mass and equal to or smaller than 8% mass. This allows further effectively inhibiting the deterioration in the solder resistance and/or the deterioration in the flowability.

While the content of the curing agent in the composition serving as the filler is not particularly limited, it is preferable to be equal to or larger than 2% mass and equal to or smaller than 50% mass over the whole composition, and more preferably equal to or larger than 2.5% mass and equal to or smaller than 40% mass, and particularly in the case of the semiconductor encapsulating resin compositions, it is preferable to be equal to or larger than 2% mass and equal to or smaller than 15% mass over the whole resin composition, and more preferably equal to or larger than 2.5% mass and equal to or smaller than 8% mass. This allows further effectively inhibiting the deterioration in the solder resistance and/or the deterioration in the flowability.

Also, the content of the curing accelerator in the composition serving as the filler is, for example, equal to or larger than 0.1% mass in the whole composition serving as the filler. This allows further effectively inhibiting the deterioration in the curability of the composition. In addition, the content of the curing accelerator is, for example, equal to or smaller than 1% mass in the whole composition. This allows further effectively inhibiting the deterioration in the flowability of the composition.

In addition to the filler composed of the functional particle group described in the above-described embodiment, various types of components may be contained in the resin composition according to the applications. More specifically, various types of additives such as: a curable resin; filler other than the functional particle group according to the present invention; a coupling agent; a coloring agent such as carbon black, colcothar and the like; a low stress component such as silicone oil, silicone rubber and the like; a demolding material such as nature wax, synthetic wax, higher fatty acid and metal salts thereof, or paraffin and the like; an inorganic ion exchanger such as hydrate of bismuth oxide and the like; a fire retardant agent such as aluminum hydroxide, magnesium hydroxide, calcium hydroxide, hydrotalcite, antimony oxide, zinc borate and the like; antioxidant; and the like may be suitably blended in the composition.

The shape of the composition may be suitably selected according to the forming method in the process for forming the composition. For example, the resin composition of the present embodiment may be in the form of the granules or the pellets for the compression molding. The form of the granules composed of the functional particle described in the above embodiments is employed, so that the agglomeration of particles is inhibited to improve the flowability of the power and reduce the adhesiveness, and therefore an adhesion into the transport path is avoided to provide reduced possibility to cause an obstacle in the transportation, and thus, the trouble such as the stagnant residence in the transportation of the resin composition of the present embodiment to the metallic mold can be firmly inhibited. Further, the loading level in the molding can be improved. Therefore, the production yield for obtaining the molded product by the compression molding can be improved. Alternatively, the resin composition of the present embodiment may be in the form of the tablets for the transfer molding.

In addition to above, also in the present embodiment similarly as in fifth embodiment, in view of improving the handling facility during the transportation or measurement and the like and enhancing the storage stability of the resin composition in the resin composition in the form of the granules, the proportion of the fine powder of smaller than 1 μm over the entire resin composition in the particle size distribution measured by employing the screen sizing using Japanese Industrial Standards (JIS) standard sieves may be, for example, equal to or lower than 5% mass, and preferably equal to or lower than 3% mass.

Further, in view of reducing the proportion of the fine powder in the granular resin composition, the particle size d10, which is defined as the size for providing the cumulative frequency of 10% measured by using a laser diffraction particle size distribution measuring device, may be, for example, equal to or larger than 3 μm, and preferably equal to or larger than 5 μm. In addition to above, the upper limit of d10 is not particularly limited, and may be defined according to the mean particle diameter and the like of the base particle, which is determined in consideration of the gate size of the metallic mold and the like, and for example, may be equal to or smaller than 10 μm.

The resin composition of the present embodiment may be preferably employed as, for example, the resin composition for the electronic component, the automotive resin composition and the powder paint.

Next, the production process for the resin composition of the present embodiment will be described. The resin composition of the present embodiment can be obtained by mixing the filler composed of the functional particle group as described in the above embodiment and other additives as required by using a mixer at an ambient temperature. Further, as far as the advantageous effect of the present invention is not deteriorated, a roll, kneading machine such as a kneader and the like or an extruder and the like may be employed to melt and knead the composition, and after cooling, the compound may be pulverized.

The resultant resin composition is molded to obtain the molded product. In order to produce the molded product, suitable molding process such as transfer molding, compression molding, injection molding and the like is utilized to carry out the cure and the molding. In the molding process, the composition or the morphology of the whole or a portion of the first layer 113 may be changed. For example, it may be permitted that the resin or the curing agent contained in the first layer 113 is cured by the molding to cause that the inorganic particle 111 derived from the filler remains in the cured product.

The resin composition for the electronic component in the present embodiment is molded to obtain the electronic component. For example, the resin composition for the electronic component in the present embodiment is used for encapsulating the semiconductor element to obtain the semiconductor device.

FIG. 3 is a cross-sectional view, showing a configuration of a semiconductor device employing the resin composition for the electronic component in the present embodiment. In the semiconductor device shown in FIG. 3, a semiconductor element 1 is fixed on a die pad 2 through a cured product of a die bond material 6. An electrode pad of the semiconductor element 1 is connected to a lead frame 4 through a gold wire 3. The semiconductor element 1 is encapsulated by a cured product 5 of an encapsulating material. The cured product 5 of the encapsulating material is a cured product of the resin composition for the electronic component of the present embodiment as described above.

According to sixth to eighth embodiments, the coated particle configured of the base particle composed of the inorganic material coated with the resin, and the coated particle coated with the curing agent for the resin, are separately produced to constitute the functional particle group so that the stable retention of the resin and the curing agent constituting the functional particle group can be achieved with the predetermined formulation. In addition to above, the variation in the aforementioned formulation caused due to the differences of the particle size can be reduced.

While the preferable embodiments of the present invention has been described in reference to the annexed figures, it is intended to present these embodiments for the purpose of illustrations of the present invention only, and various modifications other than that described above are also available.

The present invention contains the following aspects.

[1] A functional particle group containing a first coated particle constituted of a base particle composed of an inorganic material coated with a resin and a second coated particle constituted of the aforementioned base particle coated with a curing agent for the aforementioned resin.
[2] The functional particle group as described in [1], wherein the aforementioned inorganic material is silica.
[3] The functional particle group as described in [1] or [2], wherein the functional particle group contains a third coated particle constituted of the aforementioned base particle coated with a third component, which is other than the resin and the curing agent for the resin.
[4] The functional particle group as described in [3], wherein the aforementioned third component contains a curing catalyst for the aforementioned resin.
[5] The functional particle group as described in any one of [1]-[4], wherein the aforementioned third component contains a fire retardant agent.
[6] The functional particle group as described in any one of [1]-[5], wherein the aforementioned third component contains one or more of inorganic materials selected from the group consisting of silica, alumina and carbon black.
[7] The functional particle group as described in any one of [1]-[6], wherein the aforementioned third component contains a wax-type material.
[8] The functional particle group as described in any one of [1]-[7], wherein the aforementioned third component contains a liquid raw material.
[9] A filler composed of the functional particle group described in any one of [1]-[7].
[10] A resin composition for an electronic component containing the filler described in [9].
[11] An electronic component, produced by molding the resin composition for the electronic component described in [10].
[12] A semiconductor device, produced by encapsulating a semiconductor element by employing the resin composition for the electronic component described in [10].

### EXAMPLES

### Example A1

In the following examples, the functional particles having a plurality of layers on the base particles were produced. The formulations (mass ratio) of the components for the respective layers are shown in Table 1. Theta Composer commercially available from Tokuju Corporation was employed for the mechanical particle hybridizer.

TABLE 1

| | | | | | | | Comparative | Comparative |
|---|---|---|---|---|---|---|---|---|
| | | | | Example 1 | Example 2 | Example 3 | Example 1 | Example 2 |
| Formulation | Epoxy | Biphenyl | NIPPON | 6.3 | 6.3 | 6.3 | 6.3 | 6.3 |
| (Mass Ratio) | Resin | aralkyl | KAYAKU: | | | | | |
| | | epoxy | NC3000 P | | | | | |
| | | resin | | | | | | |
| | Phenolic | Biphenyl | MEIWA | 4.3 | 4.3 | 4.3 | 4.3 | 4.3 |
| | Resin | aralkyl | PLASTIC | | | | | |
| | | phenolic | INDUSTRIES: | | | | | |
| | | resin | MEH7851SS | | | | | |
| | Curing | Triphenylphosphine | | 0.2 | 0.2 | 0.2 | 0.2 | 0.2 |
| | Accelerator | | | | | | | |
| | Inorganic | Spherical | Mean Particle | 79.2 | 79.2 | 79.2 | 88.0 | 88.0 |
| | Filler | silica | Diameter: 29 μm | | | | | |
| | | Spherical | Mean Particle | 8.8 | 8.8 | 8.8 | | |
| | | silica | Diameter: 0.1 μm | | | | | |
| | Mold | Montanic | CLARIANT | 0.3 | 0.3 | 0.3 | 0.3 | 0.3 |
| | Releasing | acid wax | JAPAN | | | | | |
| | Agent | | | | | | | |
| | Ion | Hydro- | KYOWA | 0.2 | 0.2 | 0.2 | 0.2 | 0.2 |
| | Trapping | talcite | CHEMICAL | | | | | |
| | Atent | | INDUSTRY | | | | | |
| | | | DHT-4H | | | | | |

| | | | | | | |
|---|---|---|---|---|---|---|
| Coloring | Carbon black | 0.4 | 0.4 | 0.4 | 0.4 | 0.4 |
| Agent | | | | | | |
| Coupling | γ-mercapto propyl | 0.2 | 0.2 | 0.2 | 0.2 | 0.2 |
| Agent | trimethoxysilane | | | | | |
| | N-phenyl-γ-aminopropyl- | 0.1 | 0.1 | 0.1 | 0.1 | 0.1 |
| | trimethoxysilane | | | | | |

| | | | | | | |
|---|---|---|---|---|---|---|
| Evaluation | Gel Time (sec) | 44 | 43 | 46 | 90 | 45 |
| Results | Spiral Flow (cm) | 89 | 87 | 92 | 15 | 80 |
| | Tablet Formability | ∘ | ∘ | ∘ | x | ∘ |
| | Ash Uniformity (%) | 0.09 | 0.07 | 0.09 | 0.49 | 1.8 |
| | After 40° C./7 days storage stability | 91 | 89 | 92 | 46 | 53 |
| | (Spiral Flow Residual Ratio) (%) | | | | | |

### Example 1

The raw materials of the coated layer were pulverized with jet mill in advance. A single truck jet mill commercially available from Seishin Enterprise Co., Ltd. was employed for the jet mill. The conditions for the pulverization were defined as a pressure of high pressure gas of 0.6 MPa.

Fused spherical silica (mean particle diameter 29 μm and 0.1 μm) was blended in accordance with the formulation described in Table 1 to obtain inorganic filler. 88 parts (parts by mass, the same shall apply hereinafter) of the obtained inorganic filler and 0.3 part of the coupling agent were supplied to the mechanical particle hybridizer, and was stirred at the circumferential velocity of the impeller of 10 m/s for 15 minutes to carry out the coating process.

Next, the obtained coated particle and 6.3 parts of the epoxy resin were supplied in the above-described mechanical particle hybridizer, and were stirred at the circumferential velocity of the impeller of 10 m/s for 15 minutes to carry out the coating process.

Then, the obtained coated particle and 4.3 parts of the phenolic resin were Supplied to the above-described apparatus, and were stirred at the circumferential velocity of the impeller of 10 m/s for 15 minutes to carry out the coating process.

Further, the obtained coated particle, the curing accelerator, the ion trapping agent, the coloring agent and the mold releasing agent were supplied in accordance with the formulation as described in Table 1, and was stirred at the circumferential velocity of the impeller of 10 m/s for 15 minutes to carry out the coating process.

According to the above-described procedure, the functional particle, which includes the coupling agent layer (third layer 109), the epoxy resin layer (the first layer 103), and the phenolic resin layer (the curing agent layer: the lower layer 105b of the second layer 105) formed in this sequence on the inorganic particle 101 (FIG. 1(b), FIG. 2(b)), and further includes the coated layer (the upper layer 105a of the second layer 105) containing the curing accelerator, the ion trapping agent, the coloring agent and the mold releasing agent formed thereon, was obtained.

### Example 2

Fused spherical silica (mean particle diameter 29 μm and 0.1 μm) was blended in accordance with the formulation described in Table 1 to obtain inorganic filler. 88 parts of the obtained inorganic filler and 0.3 part of the coupling agent were supplied to the mechanical particle hybridizer, and was stirred at the circumferential velocity of the impeller of 10 m/s for 15 minutes to carry out the coating process.

Next, the obtained coated particle and the ion trapping agent, the coloring agent and the mold releasing agent were supplied to the similar apparatus as employed in Example 1 in accordance with the formulation described in Table 1, and was stirred at the circumferential velocity of the impeller of 10 m/s for 15 minutes to carry out the coating process.

Then, a mixture prepared by previously mixing the obtained coated particle with 4.3 parts of phenolic resin and 0.2 part of the curing accelerator, was supplied to the similar apparatus as employed in Example 1, and was stirred at the circumferential velocity of the impeller of 10 m/s for 15 minutes to carry out the coating process.

Further, the obtained coated particle and 6.3 parts of the epoxy resin were supplied, and were stirred at the circumferential velocity of the impeller of 10 m/s for 15 minutes to carry out the coating process.

According to the above-described procedure, the functional particle, which includes the coupling agent layer (the third layer 109) the coated layer containing the ion trapping agent, the mold releasing agent and the coloring agent, and the layer of mixture of the phenolic resin and the curing accelerator (the first layer 103), formed in this sequence on the inorganic particle 101 (FIG. 2(a), FIG. 2(b)) and further includes the epoxy resin layer (the second layer 105) formed thereon, was obtained.

### Example 3

Fused spherical silica (mean particle diameter 29 μm and 0.1 μm) was blended in accordance with the formulation described in Table 1 to obtain inorganic filler. 88 parts of the obtained inorganic filler and 0.3 part of the coupling agent were supplied to the similar mechanical particle hybridizer as employed in Example 1, and was stirred at the circumferential velocity of the impeller of 10 m/s for 15 minutes to carry out the coating process.

Next, the obtained coated particle and 6.3 parts of the epoxy resin were supplied to the similar mechanical particle hybridizer as employed in Example 1, and were stirred at the circumferential velocity of the impeller of 10 m/s for 15 minutes to carry out the coating process.

Then, the obtained coated particle and 0.3 part of the mold releasing agent were supplied to the similar mechanical particle hybridizer as employed in Example 1, and was stirred at the circumferential velocity of the impeller of 10 m/s for 15 minutes to carry out the coating process.

Further, the obtained coated particle and the phenolic resin, the curing accelerator, the ion trapping agent, and the coloring agent were supplied in accordance with the formulation described in Table 1 to the similar mechanical particle hybridizer as employed in Example 1, and was stirred at the circumferential velocity of the impeller of 10 m/s for 15 minutes to carry out the coating process.

According to the above-described procedure, the functional particle, which includes the coupling agent layer (the third layer 109), the epoxy resin layer (the first layer 103) and the mold releasing agent layer (the interposing layer 107) formed in this sequence on the inorganic particle 101 (FIG. 2(b)), and further includes the coated layer (the second layer 105) containing the phenolic resin, the curing accelerator, the ion trapping agent and the coloring agent formed thereon, was obtained.

### Comparative Example 1

All of the raw materials described in Table 1 were supplied to a Henschel mixer, and were pulverized and mixed to obtain present usual semiconductor encapsulating resin composition the semiconductor encapsulating resin composition of the present comparative example. The mixing conditions were at 1,000 rpm for 10 minutes.

### Comparative Example 2

The raw materials described in Table 1 were mixed at an ambient temperature with a mixer (vessel-rotatable V-shape blender). The mixing conditions were at 30 rpm for 10 minutes. The obtained mixture was melted and kneaded by employing a heating roller of 80 to 100 degrees C. for 5 minutes, and then after cooling, the mixture was pulverized to obtain the semiconductor encapsulating resin composition of the present comparative example.

Evaluations for the semiconductor encapsulating resin composition composed the functional particles obtained by Examples 1 to 3 and the semiconductor encapsulating resin compositions obtained in Comparative Examples 1 and 2 were carried out to obtain the measurement results on gel time (second), spiral flow (cm), tablet formability, ash uniformity (%) and storage stability at 40 degrees C. after 7 days (spiral flow residual ratio) (%), which are shown in Table 1. Here, these measurements were conducted by the following methods.

Gel time: Samples composed of the semiconductor encapsulating resin composition obtained in the respective Examples were placed on a hot plate of 175 degrees C., and after the sample was melted, the sample was continued to be manually kneaded with a spatula and the time taken for the cure was measured. Shorter gel time indicates faster cure rate.

Spiral flow: Low pressure transfer molding machine (commercially available from Kohtaki Precision Machine Co., Ltd, KTS-15) was employed, and the semiconductor encapsulating resin composition was injected into the metallic mold for the spiral flow measurement pursuant to EMMI-1-66 under the conditions of the metallic mold temperature of 175 degrees C., the injection pressure of 6.9 MPa, the pressure retention time of 120 seconds, and the fluidization length was measured. The result was presented by the unit of centimeter (cm). Tablet formability: Samples composed of the semiconductor encapsulating resin composition obtained in the respective Examples was punched into the tablet. The case, in which the defective situation described below was caused, was determined as X; and the case, in which the tablet was sufficiently obtained without causing a defective situation, was determined as ◯.
The defective situation: The resin was adhered onto the inner surface of the metallic mold in the tableting step and a deficit was generated in the appearance of the tablet.
Ash uniformity: Samples composed of the semiconductor encapsulating resin composition obtained in the respective Examples were mixed at an ambient temperature with a mixer (vessel-rotatable V-shape blender). The mixing conditions were at 30 rpm for 10 minutes. Sampling of the obtained mixture was conducted from five locations, and the mass ratio of the residual substance after the calcination at 700 degrees C. was measured. The result was presented by the unit of percent %. The calculation of subtracting the minimum value in the obtained measurement results from the maximum value thereof was conducted to provide the calculated value. Smaller calculated value provides better component uniformity. Storage stability at 40 degrees C. after 7 days (spiral flow residual ratio) (%) Samples composed of the semiconductor encapsulating resin composition obtained in the respective Examples were stored in the drier with the adjusted temperature at 40 degrees C. for 7 days, and after that, the spiral flow was measured, and the residual ratio (measurements after storage/measurements before storage) was obtained from the spiral flow measurement results of before and after the storage. Larger residual ratio provides smaller deteriorations of the spiral flow, and thus better storage stability.

In addition to above, concerning the semiconductor encapsulating resin composition obtained in Comparative Example 1, the sample was tattered and exhibited poor appearance in the measurement of the gel time, and did not uniformly melt. Also in the measurement of the spiral flow, the sample was tattered and the cured product was inhomogeneous.

### Example B1

In the present example, the functional particle group containing multiple types of particle having different coated layer of different materials was produced. Theta Composer commercially available from Tokuju Corporation was employed for the mechanical particle hybridizer. Also, the vessel-rotatable V-shape blender was employed for the mixer. The formulations of the raw materials in the respective particles (by mass ratio) are shown in table 2.

TABLE 2
Raw Material Formulations in Production of Coated Particles (Mass Ratio)

| | | | Coated | Coated | Coated | Coated | Coated | Coated | Coated | Coated |
|---|---|---|---|---|---|---|---|---|---|---|
| | | | Particle 1 | Particle 2 | Particle 3 | Particle 4 | Particle 5 | Particle 6 | Particle 7 | Particle 8 |
| Epoxy | Biphenyl | NIPPON | 12.0 | | | | | | | |
| Resin | aralkyl | KAYAKU: | | | | | | | | |
| | epoxy | NC 3000 P | | | | | | | | |
| | resin | | | | | | | | | |
| Phenolic | Biphenyl | MEIWA | | 12.0 | | | | | | |
| Resin | aralkyl | PLASTIC | | | | | | | | |
| | phenolic | INDUSTRIES: | | | | | | | | |
| | resin | MEH7851SS | | | | | | | | |
| Curing | Triphenylphosphine | | | | 12.0 | | | | | |
| Accelerator | | | | | | | | | | |
| Inorganic | Spherical | Mean Particle | 88.0 | 88.0 | 88.0 | 88.0 | 88.0 | 88.0 | 88.0 | 88.0 |
| Filler | silica | Diameter: 30 μm | | | | | | | | |
| Mold | Montanic | CLARIANT | | | | 12.0 | | | | |
| Releasing | acid wax | JAPAN | | | | | | | | |
| Agent | | | | | | | | | | |
| Ion | Hydro- | KYOWA | | | | | 12.0 | | | |
| Trapping | talcite | CHEMICAL | | | | | | | | |
| Atent | | INDUSTRY | | | | | | | | |
| | | DHT-4H | | | | | | | | |

| | | | | |
|---|---|---|---|---|
| Coloring | Carbon black | 12.0 | | |
| Agent | | | | |
| Coupling | γ-mercapto propyl | | 12.0 | |
| Agent | trimethoxysilane | | | |
| | N-phenyl-γ-aminopropyl- | | | 12.0 |
| | trimethoxysilane | | | |

### Example 4

In the present example, the functional particle group containing 8 types of the coated particle with different constituent materials of the coated layers was produced. The raw materials of the respective coated layers were pulverized with jet mill in advance. A single truck jet mill commercially available from Seishin Enterprise Co., Ltd. was employed for the jet mill. The conditions for the pulverization were defined as a pressure of high pressure gas of 0.6 MPa. 88 parts by mass of the inorganic filler and 12 parts by mass of the epoxy resin were supplied to the mechanical particle hybridizer to conduct the coating process to obtain the coated particle 1. Further, 88 parts by mass of the inorganic filler and 12 parts by mass of the phenolic resin were supplied to the mechanical particle hybridizer to carry out the coating process to obtain the coated particle 2. The coated particles 3 to 8 were also respectively produced by supplying the raw materials in accordance with the formulations described in Table 2 to the mechanical particle hybridizer to conduct the coating process. The conditions for the stirring process were the circumferential velocity of the impeller of 10 m/s and stirring time of 60 minutes for all particles.

The obtained coated particles 1 to 8 were blended in accordance with the mass ratio described in Table 3, and were mixed in the mixer to obtain the functional particle group of the present example.

TABLE 3
Mixing Ratio of Coated Particles (Mass Ratio)

| | Example 4 |
|---|---|
| Coated Particle 1 | 52.5 |
| Coated Particle 2 | 35.8 |
| Coated Particle 3 | 1.7 |
| Coated Particle 4 | 2.5 |
| Coated Particle 5 | 1.7 |
| Coated Particle 6 | 3.3 |
| Coated Particle 7 | 1.7 |
| Coated Particle 8 | 0.8 |

Further, in the functional particle group obtained by mixing the respective particles obtained according to the formulation of Table 2 in accordance with the formulations of Table 3, the compounding ratio of respective raw materials (parts by mass) becomes show in table 4. Further, evaluations for the functional particle group obtained in Example 4 were carried out to obtain the measurement results on gel time (second), spiral flow (cm), tablet formability, ash uniformity (%) and storage stability at 40 degrees C. after 7 days (spiral flow residual ratio) (%), which are shown in Table 4.

TABLE 4
Raw Material Ratio (Mass Ratio) in Particle Group after Mixing and Evaluation Result

| | | | | Example 4 |
|---|---|---|---|---|
| Formulation | Epoxy Resin | Biphenyl aralkyl epoxy resin | NIPPON KAYAKU: NC 3000 P | 6.3 |
| | Phenolic Resin | Biphenyl aralkyl phenolic resin | MEIWA PLASTIC INDUSTRIES: | 4.3 |
| | | | MEH7851SS | |
| | Curing Accelerator | Triphenylphosphine | | 0.2 |
| | Inorganic Filler | Spherical silica | Mean Particle Diameter: 30 μm | 88.0 |
| | Mold Releasing Agent | Montanic acid wax | CLARIANT JAPAN | 0.3 |
| | Ion Trapping Atent | Hydrotalcite | KYOWA CHEMICAL INDUSTRY | 0.2 |
| | | | DHT-4H | |

| | | |
|---|---|---|
| Coloring Agent | Carbon black | 0.4 |
| Coupling Agent | γ-mercapto propyl trimethoxysilane | 0.2 |
| | N-phenyl-γ-aminopropyltrimethoxysilane | 0.1 |

| | | |
|---|---|---|
| Evaluation | Gel Time (sec) | 44 |
| Results | Spiral Flow (cm) | 89 |
| | Tablet Formability | ◯ |
| | Ash Uniformity (%) | 0.09 |
| | After 40° C./7 days storage stability (Spiral Flow Residual Ratio) (%) | 92 |

In addition to above, in the functional particle (group) obtained in Examples 1 to 4, the proportion of fine powder of smaller than 1 μm was equal to or lower than 1% mass for each of Examples. Further, in the respective Examples, the results of the particle size d10, which is defined as the size for providing the cumulative frequency of 10% measured by using a laser diffraction particle size distribution measuring device, were: 9.0 μm for Example 1; 8.8 μm for Example 2; 9.0 μm for Example 3; and 9.1 μm for Example 4.

The present application claims the priority benefit of Japanese Patent Application No. 2010-176054, filed on Aug. 5, 2010, the whole contents of which are hereby incorporated by reference.

1. Functional particle, comprising:
a base particle composed of an inorganic material;
a first layer coating said base particle; and
a second layer coating said first layer,
wherein said first layer comprises any one or two component selected from an epoxy resin, a curing agent for said epoxy resin and a curing accelerator for said epoxy resin, and the second layer comprises the other components.

2. The functional particle according to claim 1,
wherein said first layer comprises one component selected from said epoxy resin, said curing agent and said curing accelerator, and
wherein said second layer comprises
a layer comprising one component selected from said epoxy resin, said curing agent and said curing accelerator and excluding the component contained in said first layer, and
a layer comprising the other component selected from said epoxy resin, said curing agent and said curing accelerator and excluding the component which is contained in said first layer.

3. The functional particle according to claim 1, wherein one of said first and second layers comprises said curing agent and said curing accelerator, and the other of said first and second layers comprises said epoxy resin.

4. The functional particle according to claim 1, wherein one of said first and second layers comprises said epoxy resin and said curing agent, and the other of said first and second layers contains said curing accelerator.

5. The functional particle according to claim 1, further comprising an interposing layer, wherein said interposing layer is disposed between said first layer and said second layer of said functional particle for separating said the first layer and said second layer.

6. The functional particle according to claim 5, wherein said interposing layer comprises at least one component selected from the group consisting of a metalhydroxide, a coupling agent, a mold releasing agent, an ion trapping agent, a coloring agent and a fire retardant agent.

7. The functional particle according to claim 5, wherein said interposing layer comprises at least one inorganic material selected from the group consisting of silica, alumina and silicon nitride.

8. The functional particle according to claim 5, wherein said interposing layer comprises a wax-type material as a main component.

9. The functional particle according to claim 1, further comprising a third layer provided in contact with said base particle and between said base particle and said first layer.

10. The functional particle according to claim 9, wherein said third layer comprises at least one component selected from the group consisting of a metalhydroxide, a coupling agent, a mold releasing agent, an ion trapping agent, a coloring agent and a fire retardant agent.

11. The functional particle according to claim 1, wherein material of said base particle comprises one or two or more inorganic material selected from the group consisting of silica, alumina and silicon nitride.

12. A filler composed of the functional particle according to claim 1.

13. A functional particle group, containing:
a first coated particle comprising a base particle composed of an inorganic material, wherein said base particle is coated with a resin; and
a second coated particle comprising said base particle, wherein said base particle is coated with a curing agent of said resin.

14. The functional particle group according to claim 13, wherein said inorganic material is silica.

15. The functional particle group according to claim 13, further comprising a third coated particle comprising said base particle coated with a third component other than said resin and said curing agent of the resin.

16. The functional particle group according to claim 15, wherein said third component comprises a curing catalyst of the resin.

17. The functional particle group according to claim 15, wherein said third component comprises a fire retardant agent.

18. The functional particle group according to claim 15, wherein said third component contains at least one inorganic material selected from the group consisting of silica, alumina and silicon nitride.

19. The functional particle group according to claim 15, wherein said third component comprises a wax-type material.

20. The functional particle group according to claim 15, wherein said third component comprises a liquid raw material.

21. A filler composed of the functional particle group according to claim 13.

22. The filler according to claim 12, wherein the filler is in the form of the granules, and wherein the proportion of fine powder of smaller than 1 μm over the entire filler in the particle size distribution measured by employing screen sizing using Japanese Industrial Standards (JIS) standard sieves is equal to or lower than 5% mass.

23. The filler according to claim 12, wherein the filler is in the form of the granules, and the particle size d10, which is defined as the size for providing the cumulative frequency of 10% measured by using a laser diffraction particle size distribution measuring device is equal to or larger than 3 μm.

24. A resin composition for electronic component, comprising the filler according to claim 12.

25. An electronic component obtained by molding the resin composition for electronic component according to claim 24.

26. A semiconductor device obtained by encapsulating a semiconductor element with the resin composition for electronic component according to claim 24.

27. The filler according to claim 21, wherein the filler is in the form of the granules, and wherein the proportion of fine powder of smaller than 1 μm over the entire filler in the particle size distribution measured by employing screen sizing using Japanese Industrial Standards (JIS) standard sieves is equal to or lower than 5% mass.

28. The filler according to claim 21, wherein the filler is in the form of the granules, and the particle size d10, which is defined as the size for providing the cumulative frequency of 10% measured by using a laser diffraction particle size distribution measuring device is equal to or larger than 3 μm.

29. A resin composition for electronic component, comprising the filler according to claim 21.

30. An electronic component obtained by molding the resin composition for electronic component according to claim 29.

31. A semiconductor device obtained by encapsulating a semiconductor element with the resin composition for electronic component according to claim 29.
